(19) United States
(12) Patent Application Publication
(10) Pub. No.: US 2026/0173576 A1
(43) Pub. Date: Jun. 18, 2026

(54) OPTICAL ELEMENT

(71) Applicant: HAMAMATSU PHOTONICS K.K., Hamamatsu-shi (JP)

(72) Inventor: Soh UENOYAMA, Shizuoka (JP)

(73) Assignee: HAMAMATSU PHOTONICS K.K., Hamamatsu-shi (JP)

(21) Appl. No.: 19/421,746

(22) Filed: Dec. 16, 2025

(30) Foreign Application Priority Data
Dec. 17, 2024 (JP) 2024-220853

(51) Int. Cl. H10F 77/40; H10F 30/225

(52) U.S. Cl. CPC H10F 77/413; H10F 30/225

(57) ABSTRACT

An optical element includes an APD and a light-focusing structure. The APD has a light-incidence surface and a light-receiving region, and is configured to convert light incident on the light-incidence surface into electrons in the light-receiving region and perform avalanche multiplication of the electrons. The light-focusing structure has a nanostructure provided on the light-incidence surface of the APD. The nanostructure has a plurality of first unit structures arranged along the light-incidence surface. A period of the plurality of first unit structures is equal to or greater than a wavelength of the light. The light-focusing structure focuses diffracted light into the light-receiving region by individually modulating a phase of ±n-th order (n>0) diffracted light in each of the first unit structures.

### CROSS-REFERENCE TO RELATED APPLICATIONS

This application claims priority to Japanese Patent Application No. 2024-220853 filed on Dec. 17, 2024, the entire contents of which are incorporated herein by reference.

### TECHNICAL FIELD

The present disclosure relates to an optical element.

### BACKGROUND

U.S. Patent Application Publication No. 2020-98814 discloses a configuration in which a meta-lens is arranged above a photodiode. Japanese Unexamined Patent Application Publication No. 2006-100515 discloses a solid-state imaging device including a plurality of pixels. Philippe Lalanne and Pierre Chavel, “ON THE PREHISTORY OF OPTICAL METASURFACES,” Photoniques, Vol. 119, pp. 41-45 discloses a metasurface technology.

### SUMMARY

A technology for focusing light using a meta-lens is used for an optical element such as a photodiode. A conventional meta-lens has a feature of including a plurality of unit structures arranged along a light-incidence surface of an optical element, and a period of the plurality of unit structures is less than a wavelength of incident light. A propagation direction of light emitted from such a conventional meta-lens coincides with a propagation direction of the incident light, and becomes, for example, perpendicular to the light-incidence surface. On the other hand, depending on the optical element, it may be desired to largely incline the propagation direction of focused light from a normal direction of the light-incidence surface in a region close to the light-incidence surface. For example, in a photodiode, the longer an optical path in a light-receiving region that converts light into electrons, the higher the quantum efficiency of photoelectric conversion can be. With a conventional meta-lens, since the propagation direction of the emitted light coincides with the propagation direction of the incident light, it is difficult to lengthen the optical path of the focused light in a region close to the light-incidence surface.

An object of the present disclosure is to provide an optical element including a light-focusing structure capable of largely inclining a propagation direction of focused light from a normal direction of a light-incidence surface.

An optical element according to an aspect of the present disclosure includes an optical component and a light-focusing structure. The optical component has a light-incidence surface on which light is incident. The light-focusing structure has a nanostructure provided on the light-incidence surface of the optical component. The nanostructure has a plurality of first unit structures arranged along the light-incidence surface. An arrangement period of the plurality of first unit structures is equal to or greater than a wavelength of the light. The light-focusing structure focuses diffracted light by individually modulating a phase of ±n-th order (n>0) diffracted light of the light in each of the plurality of first unit structures.

According to the present disclosure, it is possible to provide an optical element including a light-focusing structure capable of largely inclining a propagation direction of focused light from a normal direction of a light-incidence surface.

The present invention will be more fully understood from the detailed description given herein below and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a cross-sectional view showing a configuration of an optical element according to an embodiment of the present disclosure.

FIG. 2 is a diagram schematically showing a side cross-section of one unit structure included in a nanostructure when a film mainly comprises metal.

FIG. 3 is a graph showing a relationship between a reflectance (%) of a nanostructure and a wavelength (nm) of incident light when a film mainly comprises metal.

FIG. 4 is a diagram schematically showing a side cross-section of one unit structure included in a nanostructure when a film mainly comprises dielectric material.

FIG. 5 is a graph showing a relationship between a reflectance (%) of a nanostructure and a wavelength (nm) of incident light when a film mainly comprises dielectric material.

FIGS. 6A and 6B are graphs showing a relationship between a wavelength and a light absorption enhancement factor.

FIGS. 7A to 7E are plan views of a unit structure.

FIGS. 8A to 8E are side views of the unit structure, corresponding to FIGS. 7A to 7E, respectively.

FIG. 9 is a diagram conceptually showing a state of light diffraction in a plurality of unit structures.

FIG. 10 is a diagram conceptually showing a state of light diffraction in a plurality of unit structures.

FIG. 11 is a diagram conceptually showing a state of light collection by a nanostructure in an optical element.

FIG. 12 is a diagram conceptually showing a state of light collection by a nanostructure in an optical element.

FIG. 13 is a diagram conceptually showing a state of light collection by a nanostructure in an optical element.

FIG. 14 is a diagram conceptually showing a state of light collection by a nanostructure in an optical element.

FIG. 15 is a diagram conceptually showing a state of light collection by a nanostructure in an optical element.

FIG. 16 is a diagram conceptually showing a state of light collection when a meta-lens is provided on a light-incidence surface instead of a nanostructure, as a reference example.

FIG. 17 is a cross-sectional view showing a configuration of an optical element according to a reference example.

FIG. 18 is a cross-sectional view showing a configuration of an optical element according to another reference example.

FIGS. 19A to 19E are plan views showing a unit structure according to a modification.

FIGS. 20A to 20E are plan views showing a unit structure according to a modification.

FIGS. 21A to 21E are plan views showing a unit structure according to a modification.

FIGS. 22A to 22E are plan views showing a unit structure according to a modification.

FIGS. 23A to 23E are plan views showing a unit structure according to a modification.

FIGS. 24A to 24E are side views of a unit structure according to a modification.

FIG. 25 is a diagram schematically showing a configuration according to a modification.

FIGS. 26A to 26D are diagrams showing a manufacturing process of a nanostructure.

FIG. 27 is a diagram schematically showing a cross-sectional configuration of an optical element according to a modification.

FIGS. 28A to 28C are graphs showing a relationship between a wavelength and a light absorption enhancement factor in a simulation.

FIGS. 29A to 29C are graphs showing a relationship between a wavelength and a light absorption enhancement factor in a simulation.

FIGS. 30A to 30C are graphs showing a relationship between a wavelength and a light absorption enhancement factor in a simulation.

FIGS. 31A and 31B are graphs showing a relationship between a wavelength and light absorption and a light absorption enhancement factor of an APD in a simulation.

FIGS. 32A and 32B are graphs showing a relationship between a wavelength and a reflectance and a transmittance of a nanostructure in a certain structure in a simulation.

FIG. 33 is a graph showing a relationship between a wavelength and light absorption of an APD in a certain structure in a simulation.

FIGS. 34A and 34B are graphs showing a relationship between a wavelength and a reflectance in a simulation.

FIGS. 35A to 35D are graphs showing simulation results when a nanostructured film is composed of silicon (Si) and an anti-reflection film composed of an Al₂O₃ film is provided.

FIGS. 36A to 36D are graphs showing simulation results when a nanostructured film is composed of Si and an anti-reflection film composed of an Al₂O₃ film is provided.

FIGS. 37A to 37D are graphs showing simulation results when a nanostructured film is composed of Si and an anti-reflection film composed of an Al₂O₃ film is provided.

FIGS. 38A to 38D are graphs showing simulation results when a nanostructured film is composed of Si and an anti-reflection film composed of an SiO₂ film is provided.

FIGS. 39A to 39D are graphs showing simulation results when a nanostructured film is composed of Si and an anti-reflection film composed of an SiO₂ film is provided.

FIGS. 40A to 40D are graphs showing simulation results when a nanostructured film is composed of Si and an anti-reflection film composed of an SiO₂ film is provided.

FIGS. 41A to 41D are graphs showing simulation results.

FIGS. 42A to 42D are graphs showing simulation results.

FIGS. 43A to 43D are graphs showing simulation results.

FIGS. 44A to 44D are optical microscope images showing nanostructures.

FIGS. 45A to 45D are scanning electron microscope images showing nanostructures.

FIGS. 46A and 46B are graphs showing a relationship between a wavelength and a reflectance of a fabricated nanostructure, and a relationship between a wavelength and a light absorption enhancement factor of an optical element.

### DETAILED DESCRIPTION

Specific examples of the present disclosure will be described below with reference to the drawings. The present invention is not limited to these examples, but is indicated by the claims, and is intended to include all modifications within the meaning and scope equivalent to the claims. In the following description, the same elements in the description of the drawings are denoted by the same reference numerals, and redundant description will be omitted.

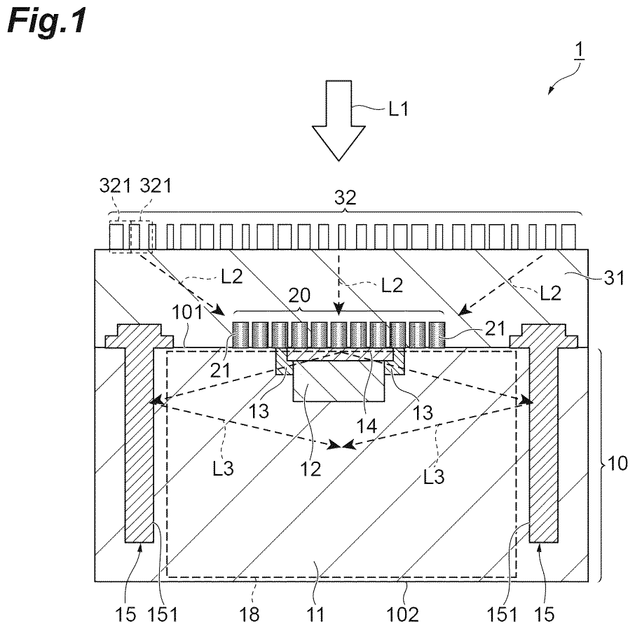

FIG. 1 is a cross-sectional view showing a configuration of an optical element 1 according to an embodiment of the present disclosure. As shown in FIG. 1, the optical element 1 of the present embodiment includes an avalanche photodiode (APD) 10, a reflecting portion 15, a nanostructure 20, a light-transmitting layer 31, and a meta-lens 32. The nanostructure 20 is provided on a light-incidence surface 101 of the APD 10. The light-transmitting layer 31 is provided over the light-incidence surface 101 of the APD 10 and covers the nanostructure 20. The meta-lens 32 is provided on a surface of the light-transmitting layer 31. Light L1 is incident on the surface of the light-transmitting layer 31 via the meta-lens 32. The light L1 is, for example, infrared light. The meta-lens 32 focuses the light L1 toward the nanostructure 20 to generate convergent light L2, and causes the convergent light L2 to be incident on the light-transmitting layer 31. The convergent light L2 travels through the light-transmitting layer 31 and reaches the nanostructure 20. The nanostructure 20 diffracts the convergent light L2 to generate diffracted light L3, and cooperates with the reflecting portion 15 to focus the diffracted light L3 within the APD 10. The APD 10 generates a current signal corresponding to a light intensity of the diffracted light L3. The light-transmitting layer 31 and the meta-lens 32 may be omitted if not necessary. In that case, the nanostructure 20 diffracts the light L1 to generate the diffracted light L3. Hereinafter, each component of the optical element 1 will be described in detail.

The meta-lens 32 has a plurality of unit structures 321 (second unit structures) arranged along the light-incidence surface 101 of the APD 10. Only two unit structures 321 are explicitly shown in the figure, and illustration of the other unit structures 321 is omitted. An arrangement period of the plurality of unit structures 321 is less than a wavelength of the light L1. The meta-lens 32 individually modulates a phase of 0-th order light included in the light L1 in each of the plurality of unit structures 321. Thereby, the meta-lens 32 converts the light L1 into the convergent light L2 that converges toward the nanostructure 20. Specifically, the meta-lens 32 is composed of a plurality of films. The plurality of films are, for example, metal films or dielectric films. Each of the plurality of unit structures 321 has a slit extending in a predetermined direction. Then, a relative position of a center of the slit of each of the plurality of unit structures 321 with respect to a center of each of the plurality of unit structures 321 in a direction intersecting the predetermined direction is determined according to the phase.

The convergent light L2 passes through the light-transmitting layer 31 to reach the nanostructure 20. The light-transmitting layer 31 is composed of a material such as SiO₂ or Si, for example.

The nanostructure 20 constitutes a part of the light-focusing structure in the present embodiment. The nanostructure 20 is located between the meta-lens 32 and the light-incidence surface 101 of the APD 10, and is provided on the light-incidence surface 101 in the illustrated example. The nanostructure 20 includes a plurality of films 21 arranged along the light-incidence surface 101. The film 21 mainly comprises metal or dielectric material. Examples of the metal constituting the film 21 include gold (Au), silver (Ag), and aluminum (Al). Examples of the dielectric material constituting the film 21 include TiO₂, SiO₂, HfO₂, SiN, and a-Si.

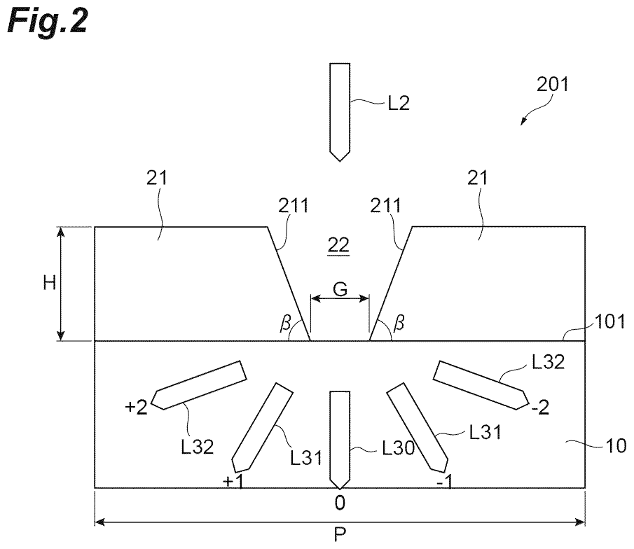

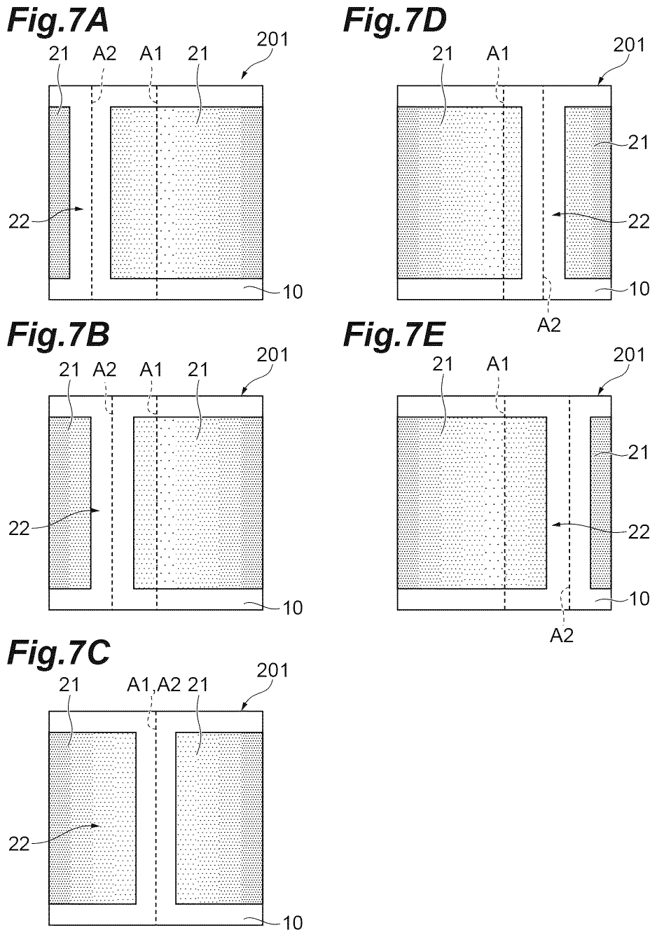

FIG. 2 is a diagram schematically showing a side cross-section of one unit structure 201 included in the nanostructure 20 when the film 21 mainly comprises metal. The nanostructure 20 has a plurality of unit structures 201 (first unit structures) arranged along the light-incidence surface 101. The plurality of unit structures 201 are arranged, for example, in a lattice pattern (matrix pattern). A period P of the plurality of unit structures 201 is equal to or greater than the wavelength of the light L1. That is, the period P of the plurality of unit structures 201 is the same as or longer than the wavelength of the light L1. The period P is, for example, 520 nm. Each unit structure 201 is configured by a pair of adjacent films 21 and a slit 22 provided between the pair of films 21. The slit 22 extends in a predetermined direction along the light-incidence surface 101. As shown in FIGS. 7A to 7E to be described later, the pair of films 21 do not reach both ends of the unit structure 201 in the predetermined direction, and are spaced apart from a pair of films 21 of an adjacent unit structure 201 in the predetermined direction. When the film 21 of each unit structure 201 mainly comprises metal, the nanostructure 20 diffracts the convergent light L2 (or the light L1 when the meta-lens 32 is not provided) by surface plasmon resonance, and causes ±n-th order (n>0, for example, n≥2) diffracted light L3 to travel in a direction intersecting a normal direction of the light-incidence surface 101. FIG. 2 shows 0-th order light L30, ±1st order diffracted light L31, and ±2nd order diffracted light L32. The larger the order of the diffracted light L3, the larger the inclination of the propagation direction of the diffracted light L3 with respect to the normal direction of the light-incidence surface 101. The diffracted light L3 of a negative order is diffracted to a side opposite to the diffracted light L3 of a positive order. In the present embodiment, the ±1st order diffracted light L31 or the ±2nd order diffracted light L32 is used as the diffracted light L3, and the 0-th order light L30 is not used. An angle of the propagation direction of the diffracted light L3 with respect to the normal direction of the light-incidence surface 101 is, for example, 80°.

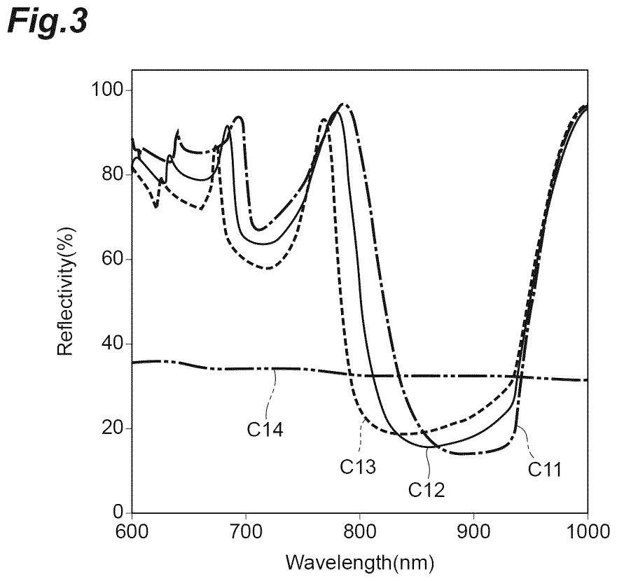

When the film 21 mainly comprises metal, the slit 22 is formed by, for example, wet etching, and a width of the slit 22 becomes wider as a distance from the light-incidence surface 101 increases. Therefore, an inner side surface 211 of the slit 22 is inclined with respect to a normal direction of the light-incidence surface 101. An angle β formed between the light-incidence surface 101 and the inner side surface 211 is, for example, 50° or more and less than 90°. The angle β is, for example, 65°. A thickness of the film 21, that is, a height H of a surface of the film 21 with respect to the light-incidence surface 101, is, for example, 200 nm. A diffraction efficiency of the nanostructure 20 depends on the height H. A minimum width G of the slit 22 is, for example, 60 nm or more and 100 nm or less. FIG. 3 is a graph showing a relationship between a reflectance (%) of the nanostructure 20 and a wavelength (nm) of the light L1 when the film 21 mainly comprises metal. In FIG. 3, a curve C11 indicates a case where the width G is 60 nm, a curve C12 indicates a case where the width G is 80 nm, and a curve C13 indicates a case where the width G is 100 nm. A curve C14 indicates a case where the nanostructure 20 is not provided. As shown in FIG. 3, the reflectance of the nanostructure 20 varies according to the wavelength of the incident light, but there is a wavelength band in which the reflectance is smaller than in the case where the nanostructure 20 is not provided. Therefore, by appropriately setting the width G of the slit 22, the nanostructure 20 can also function as a wavelength filter.

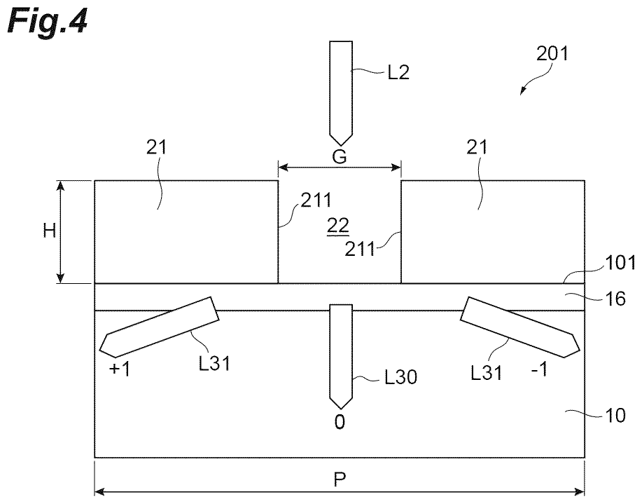

FIG. 4 is a diagram schematically showing a side cross-section of one unit structure 201 included in the nanostructure 20 when the film 21 mainly comprises dielectric material. Also in this example, a period P of the plurality of unit structures 201 is equal to or greater than the wavelength of the light L1. The period P is, for example, 330 nm. Even when the film 21 of each unit structure 201 mainly comprises dielectric material, the nanostructure 20 diffracts the convergent light L2 (or the light L1 when the meta-lens 32 is not provided) and causes ±n-th order (n>0) diffracted light L3 to travel in a direction intersecting a normal direction of the light-incidence surface 101. FIG. 4 shows 0-th order light L30 and ±1st order diffracted light L31. In the present embodiment, the ±1st order diffracted light L31 is used as the diffracted light L3, and the 0-th order light L30 is not used. When the film 21 mainly comprises dielectric material, the slit 22 is formed by, for example, dry etching, and a width of the slit 22 is constant regardless of a distance from the light-incidence surface 101. Therefore, an inner side surface 211 of the slit 22 is perpendicular to the light-incidence surface 101.

When the film 21 mainly comprises dielectric material, an anti-reflection film 16 is provided on the APD 10 as necessary. The anti-reflection film 16 may be composed of a material having etching selectivity with respect to the film 21. In that case, the anti-reflection film 16 also functions as an etching stop layer for the film 21. When the film 21 mainly comprises silicon, the anti-reflection film 16 mainly comprises, for example, SiO₂ or Al₂O₃. The anti-reflection film 16 constitutes the light-incidence surface 101.

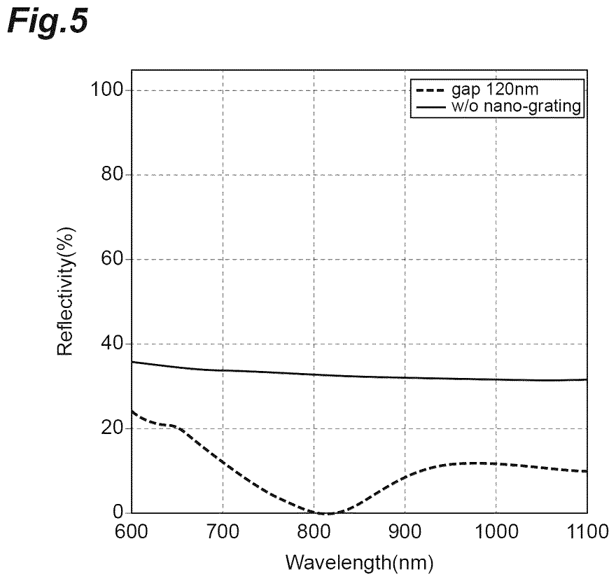

FIG. 5 is a graph showing a relationship between a reflectance (%) of the nanostructure 20 and a wavelength (nm) of the light L1 when the film 21 mainly comprises dielectric material. In FIG. 5, a dashed line indicates a case where a width G of the slit 22 is 120 nm. A solid line indicates a case where the nanostructure 20 is not provided. As shown in FIG. 5, the reflectance of the nanostructure 20 varies according to the wavelength of the incident light, but, over the entire wavelength range, the reflectance is smaller than in the case where the nanostructure 20 is not provided. Therefore, the nanostructure 20 can also function as an anti-reflection film.

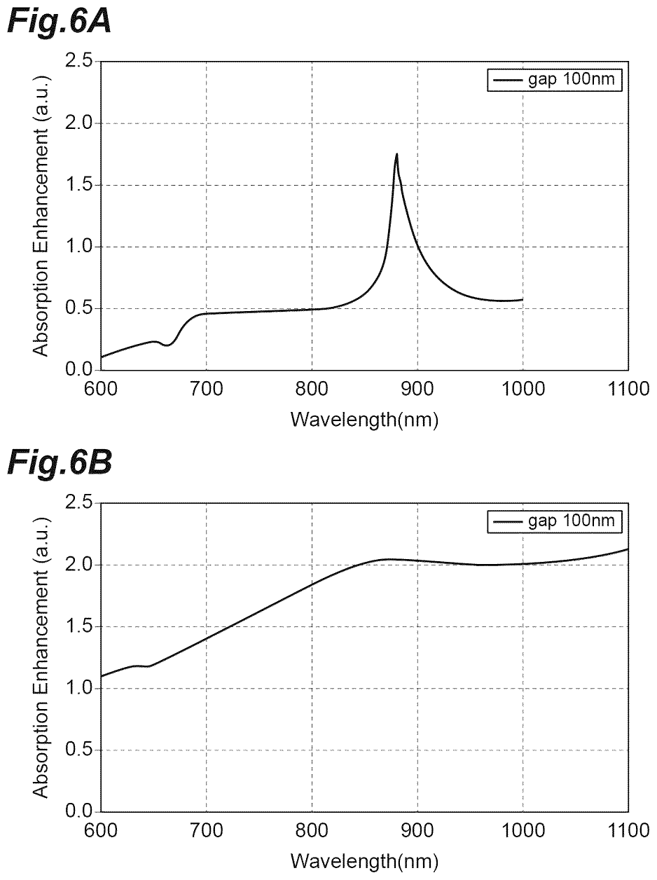

FIGS. 6A and 6B are a graph showing a relationship between a wavelength of the light L1 and a light absorption enhancement factor (Absorption Enhancement) of the APD 10 when a width G is 100 nm. A value of the light absorption enhancement factor is a normalized value with a case where the nanostructure 20 is not provided being 1. Specifically, the light absorption enhancement factor PE is calculated by the following mathematical formula. Here, I_{sig} is a photocurrent generated in the APD 10 when the nanostructure 20 is provided, I_{ref} is a photocurrent generated in the APD 10 when the nanostructure 20 is not provided, and I_{dark} is a dark current generated in the APD 10.

$$PE = ( {I}_{sig} - {I}_{dark} ) / ( {I}_{ref} - {I}_{dark} )$$

FIG. 6A shows a case where the film 21 mainly comprises metal, and FIG. 6B shows a case where the film 21 mainly comprises dielectric material. As shown in FIGS. 6A and 6B, when the film 21 mainly comprises metal, a sensitivity of the optical element 1 can be improved at a specific wavelength (for example, 870 nm to 900 nm), and when the film 21 mainly comprises dielectric material, the sensitivity of the optical element 1 can be improved over a broad wavelength range.

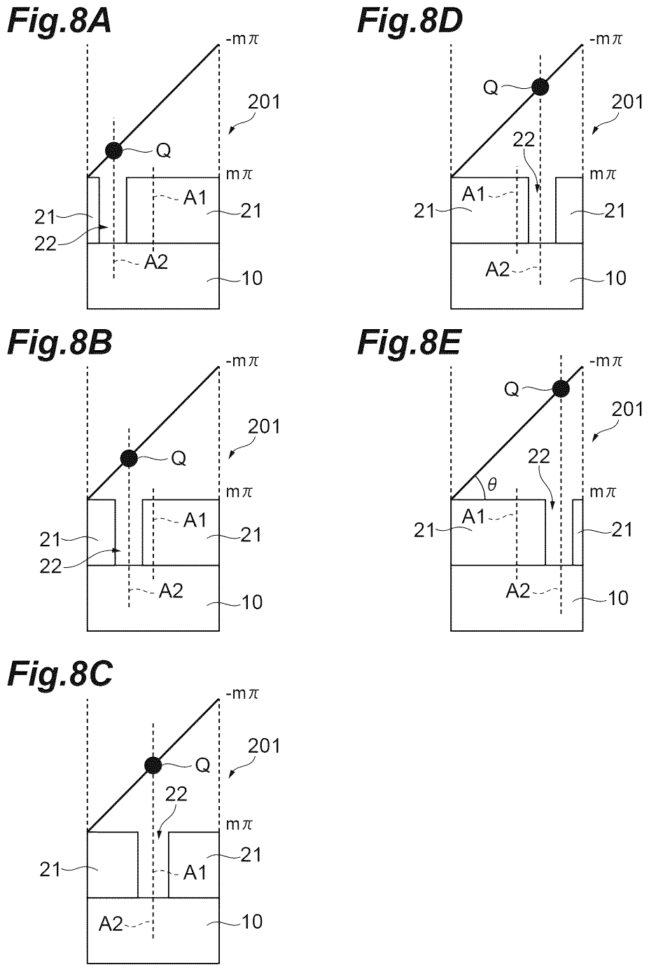

FIGS. 7A to 7E are plan views of the unit structure 201. FIGS. 8A to 8E are side views of the unit structure 201, corresponding to FIGS. 7A to 7E, respectively. As shown in FIGS. 7A to 7E and 8A to 8E, in each unit structure 201, a relative position of a center line A2 of the slit 22 with respect to a center line A1 of the unit structure 201 is individually set for each unit structure 201. Then, as shown in FIGS. 8A to 8E, a phase of the diffracted light L3 is controlled according to the relative position of the center line A2 of the slit 22 with respect to the center line A1 of the unit structure 201. A point Q in FIGS. 8A to 8E indicates a magnitude of the phase of the diffracted light L3 (mπ (rad) to −mπ (rad), where m is an integer of 1 or more) corresponding to the position of the center line A2. In the examples shown in FIGS. 8A to 8E, the phase of the diffracted light L3 is largest in FIG. 8A, and the phase of the diffracted light L3 is smallest in FIG. 8E. A diffraction angle θ is also shown in FIG. 8E.

In this way, in each unit structure 201, the relative position of the center line A2 of the slit 22 with respect to the center line A1 is determined according to a phase to be set for the diffracted light L3 emitted from each unit structure 201. Thereby, the nanostructure 20 individually modulates the phase of the diffracted light L3 in each of the plurality of unit structures 201. Then, the nanostructure 20 functions as a condensing lens that focuses the diffracted light L3 into an inside of the APD 10 (specifically, a semiconductor region 11 described later). In one example, a phase distribution of the diffracted light L3 emitted from the nanostructure 20 satisfies the following mathematical formula (1). Here, φ_{Lens} (x, y) is the phase at a coordinate position (x, y) on the light-incidence surface 101, λ is the wavelength of the light, f is a focal length of the nanostructure 20, kₓ is an arbitrary coefficient including 0, α is α=π/2−θ (rad), and α≥0. Here, kₓ sin α in the mathematical formula (1) is a phase correction term.

$$\begin{matrix}[ Math . 1 ] & \\ {ϕ}_{Lens} ( x , y ) = - \frac{2 π}{λ} ( \sqrt{{x}^{2} + {y}^{2} + {f}^{2}} - f ) + {k}_{x} sin α & ( 1 )\end{matrix}$$

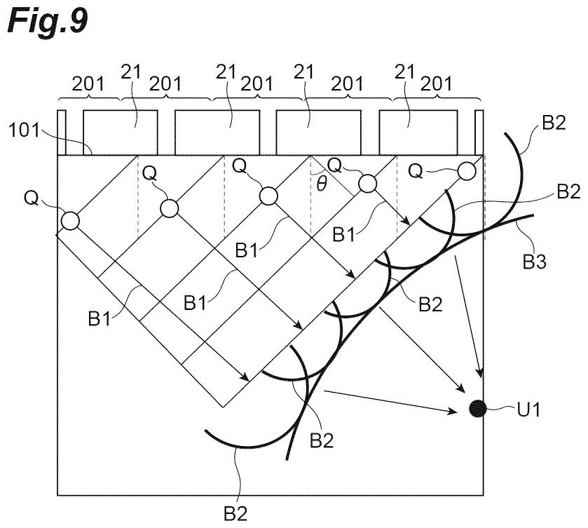

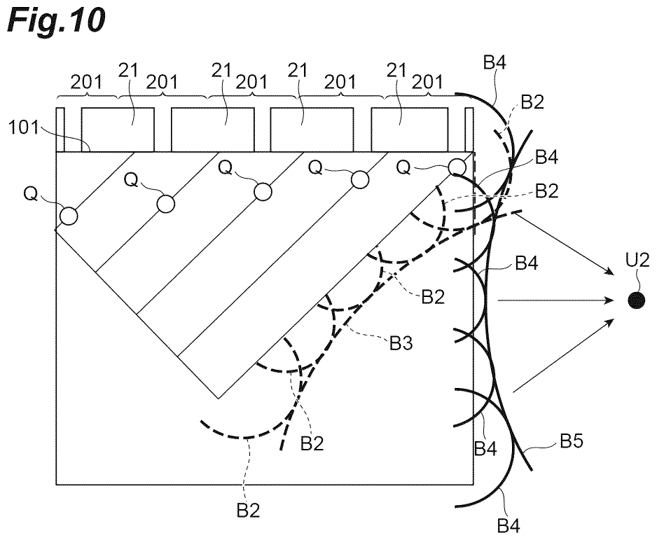

FIGS. 9 and 10 are diagrams conceptually showing a state of light diffraction in the plurality of unit structures 201. FIG. 9 shows a case where there is no phase correction term in the mathematical formula (1), and FIG. 10 shows a case where there is a phase correction term in the mathematical formula (1). In the figures, an arrow B1 represents a propagation direction of the diffracted light L3, and a point Q represents a phase of the diffracted light L3. A semicircle B2 represents a wavefront of the diffracted light L3 emitted from each unit structure 201 when there is no phase correction term in the mathematical formula (1) (that is, kₓ=0). A curve B3 and a point U1 represent a combined wavefront and a focal point, respectively, when there is no phase correction term in the mathematical formula (1). A semicircle B4 represents a wavefront of the diffracted light L3 emitted from each unit structure 201 when there is a phase correction term in the mathematical formula (1). A curve B5 and a point U2 represent a combined wavefront and a focal point, respectively, when there is a phase correction term in the mathematical formula (1). As shown in FIG. 9, when the nanostructure 20 individually modulates the phase of the diffracted light L3 in each unit structure 201, the diffracted light L3 can be focused at a point U1. In addition, as shown in FIG. 10, when the nanostructure 20 individually modulates the phase of the diffracted light L3 in each unit structure 201 and additionally corrects the phase, the diffracted light L3 can be focused at a point U2 closer to the light-incidence surface 101 than the point U1.

The nanostructure 20 has a diffractive effect and a light-focusing effect only in a plane intersecting an extending direction (predetermined direction) of the slit 22. Therefore, since only a light component having a polarization plane along the plane is diffracted and focused, the nanostructure 20 can also function as a polarization filter.

Referring to FIG. 1 again, the APD 10 is the optical component in the present embodiment. The APD 10 has a light-incidence surface 101 and a back surface 102. The light-incidence surface 101 and the back surface 102 are, for example, flat surfaces parallel to each other. The APD 10 is a photodiode that utilizes avalanche multiplication, and converts light incident on the light-incidence surface 101 into electrons in a light-receiving region and performs avalanche multiplication of the electrons. In the APD 10, electrons are multiplied by application of a reverse bias voltage. The APD 10 has one or a plurality of pixel portions 18. FIG. 1 shows a pixel portion 18. The plurality of pixel portions 18 may be arranged, for example, in a lattice pattern (matrix pattern), or may be aligned in one direction along the light-incidence surface 101.

The pixel portion 18 has, for example, a rectangular shape when viewed from a direction perpendicular to the light-incidence surface 101. The pixel portion 18 is formed in a semiconductor substrate such as a silicon (Si) substrate. The pixel portion 18 has an n-type semiconductor region 11, a high-concentration n-type semiconductor region 12, a p-type semiconductor region 13, and a high-concentration p-type semiconductor region 14. The semiconductor regions 12 and 14 perform avalanche multiplication of electrons. The semiconductor region 11 is, for example, a substrate region. The semiconductor region 11 constitutes the back surface 102 of the APD 10. The semiconductor regions 12, 13, and 14 are formed, for example, by ion implantation into the semiconductor region 11. The semiconductor regions 12 and 14 form a pn junction with each other. The semiconductor region 11, together with the semiconductor regions 12 and 14, functions as a sensitive region (light-receiving region) that is sensitive to incident light. The sensitive region is sensitive to light, for example, in a near-infrared region (for example, 750 nm to 2.5 μm). The semiconductor region 14 constitutes a part of the light-incidence surface 101. The semiconductor region 11 constitutes the rest of the light-incidence surface 101.

The APD 10 has, for example, electrodes on a light-incidence surface 101 side and a back surface 102 side, respectively. A reverse bias voltage is applied to the APD 10 via these electrodes. The APD 10 operates, for example, in a Geiger mode, and in that case, a reverse bias voltage equal to or higher than a breakdown voltage is applied. The APD 10 may operate in a linear mode, and in that case, a reverse bias voltage smaller than the breakdown voltage is applied.

The reflecting portion 15 (first reflecting portion) is provided over the entire circumference of an outer edge of the pixel portion 18. The reflecting portion 15 is provided on a side opposite to the nanostructure 20 with respect to the light-incidence surface 101, and is arranged to enclose the nanostructure 20 when viewed from a direction perpendicular to the light-incidence surface 101. The reflecting portion 15 extends from the light-incidence surface 101 in a thickness direction of the APD 10. The reflecting portion 15 functions as a low-sensitivity region that is insensitive (or has low sensitivity) to incident light. The reflecting portion 15 is formed, for example, by embedding a metal material in a groove (trench) formed in the light-incidence surface 101.

The reflecting portion 15 constitutes a part of the light-focusing structure in the present embodiment, and has a light reflecting surface 151 (first light reflecting surface). The light reflecting surface 151 faces the inside of the enclosure in which the reflecting portion 15 encloses the nanostructure 20. The light reflecting surface 151 reflects the diffracted light L3 during focusing and emitted from the nanostructure 20, toward a focal point in the APD 10.

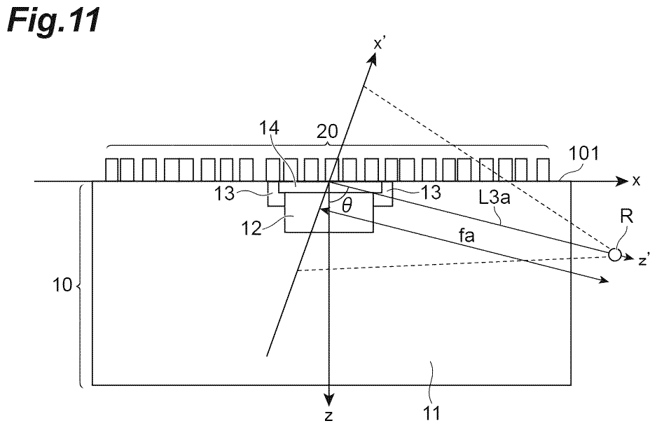

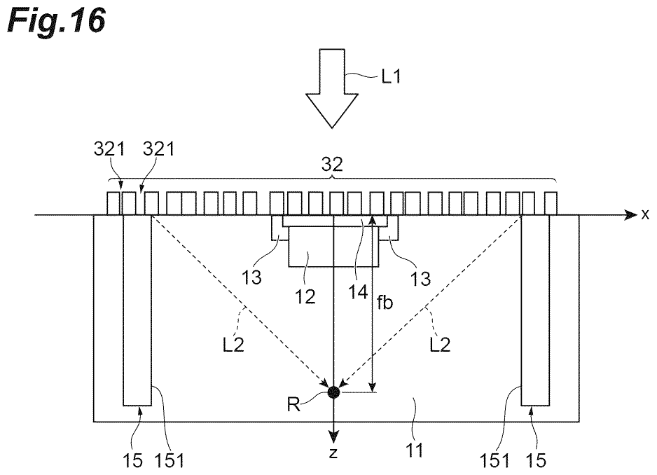

FIGS. 11 to 15 are diagrams conceptually showing a state of light collection by the nanostructure 20 in the optical element 1. FIG. 16 is a diagram conceptually showing a state of light collection when a meta-lens 32 is provided on the light-incidence surface 101 instead of the nanostructure 20, as a reference example. In each figure, xz coordinate axes are shown. The x-axis is parallel to the light-incidence surface 101. The z-axis is parallel to a normal direction of the light-incidence surface 101. As shown in FIG. 16, when the meta-lens 32 is provided on the light-incidence surface 101, the meta-lens 32 modulates a phase of 0-th order light, so that a center line of the convergent light L2 becomes perpendicular to the light-incidence surface 101, and a focal point R is formed at a position of a focal length fb from a center of the meta-lens 32 along a z-axis direction (that is, the normal direction of the light-incidence surface 101).

FIG. 11 shows a state where the reflecting portion 15 is not provided in the present embodiment including the nanostructure 20. A center line (z′-axis) of +n-th order (n>0) diffracted light L3a emitted from the nanostructure 20 forms a diffraction angle θ with respect to a normal direction (z-axis) of the light-incidence surface 101. Then, when there is no reflecting portion 15, a focal point R is formed at a position of a focal length fa from a center of the nanostructure 20 in a direction inclined with respect to the normal direction of the light-incidence surface 101. A distance between the light-incidence surface 101 and the focal point R is significantly shorter than in a case where the meta-lens 32 is provided instead of the nanostructure 20.

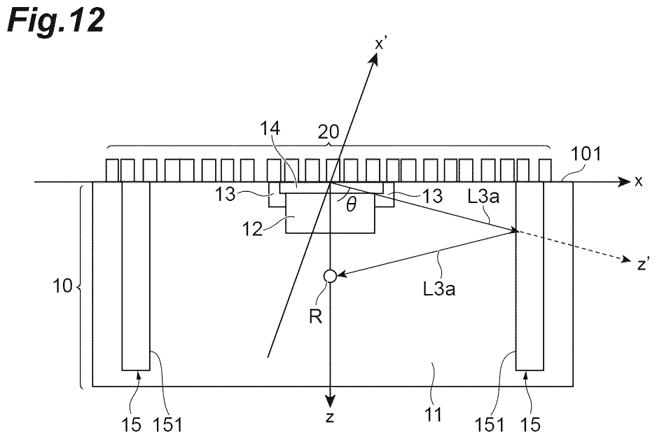

FIG. 12 shows a state where the reflecting portion 15 is provided. By providing the reflecting portion 15 during focusing of the diffracted light L3, the focusing +n-th order diffracted light L3a is reflected at the light reflecting surface 151. Thereby, a position of the focal point R moves to a position directly below a center of the nanostructure 20, that is, near a center line of the APD 10 perpendicular to the light-incidence surface 101. Even in this case, a distance between the light-incidence surface 101 and the focal point R is significantly shorter than in a case where the meta-lens 32 is provided instead of the nanostructure 20.

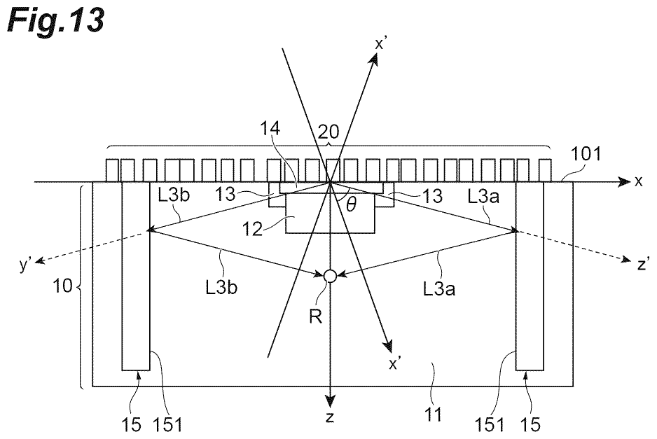

FIG. 13 further shows-n-th order (n>0) diffracted light L3b in addition to the +n-th order (n>0) diffracted light L3a. A propagation direction of the −n-th order diffracted light L3b is line-symmetrical to a propagation direction of the +n-th order diffracted light L3a with respect to a center line of the APD 10 perpendicular to the light-incidence surface 101. Therefore, after the focusing −n-th order diffracted light L3b is reflected at the light reflecting surface 151, a position of a focal point R of the −n-th order diffracted light L3b coincides with a position of a focal point R of the +n-th order diffracted light L3a.

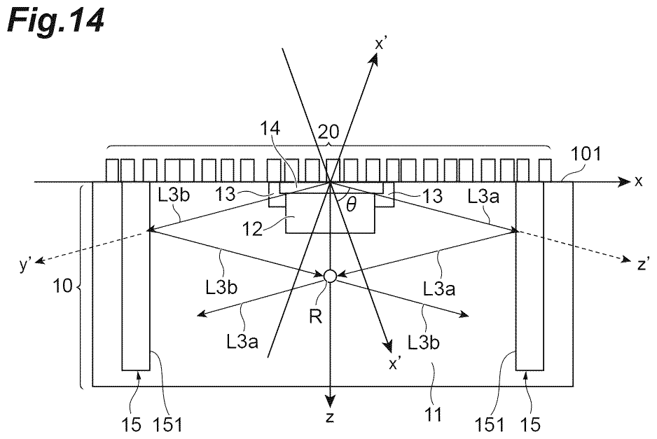

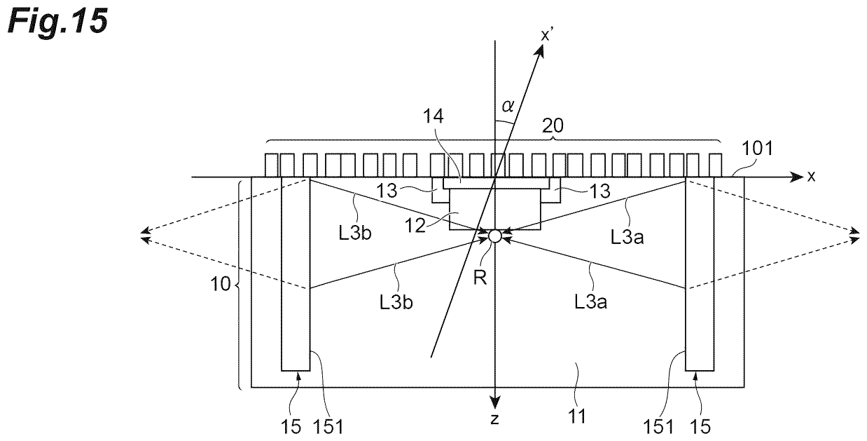

However, as shown in FIG. 14, the ±n-th order diffracted light L3a and L3b, after being focused at the focal point R, diverge downward from the focal point R. Therefore, as shown in the mathematical formula (1) described above, a phase correction term kₓ sin α may be introduced into a phase distribution of the diffracted light L3a and L3b emitted from the nanostructure 20. Thereby, as shown in FIG. 15, propagation directions of the ±n-th order diffracted light L3a and L3b approach a direction along the light-incidence surface 101, and the ±n-th order diffracted light L3a and L3b can be focused in the direction along the light-incidence surface 101, that is, in a lateral direction. Therefore, it is possible to suppress the ±n-th order diffracted light L3a and L3b from diffusing downward after being focused at the focal point R.

Effects obtained by the optical element 1 of the present embodiment described above will be described. In the optical element 1 of the present embodiment, the nanostructure 20 having a light-focusing structure is provided on the light-incidence surface 101 of the APD 10. A period P of the plurality of unit structures 201 of the nanostructure 20 is equal to or greater than the wavelength of the light L1, unlike a conventional meta-lens. Then, the light-focusing structure focuses the diffracted light L3 into the inside of the APD 10 by individually modulating a phase of ±n-th order (n>0) diffracted light L3 in each unit structure 201. Such a light-focusing structure focuses ±n-th order (n>0) diffracted light L3 such as ±1st order and ±2nd order, instead of focusing 0-th order light like a conventional meta-lens. Then, a propagation direction of the ±n-th order diffracted light L3 is largely inclined with respect to a propagation direction of the convergent light L2 (or the light L1 when the meta-lens 32 is not provided). That is, according to the optical element 1 of the present embodiment, the propagation direction of the focused diffracted light L3 can be largely inclined from a normal direction of the light-incidence surface 101, as compared with a conventional meta-lens. Then, an optical path in the light-receiving region (semiconductor region 11) can be lengthened to increase a quantum efficiency of photoelectric conversion. Furthermore, by forming a focal point R in the light-receiving region, an avalanche probability can also be increased. As a result, a light receiving sensitivity of the APD 10 can be increased.

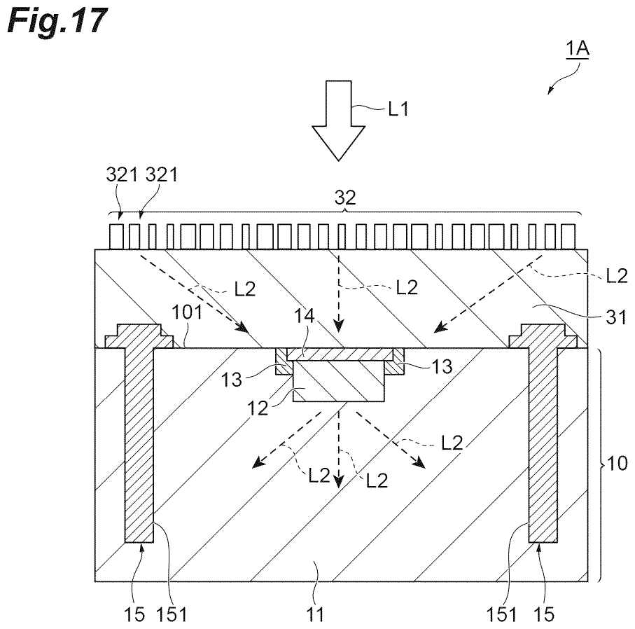

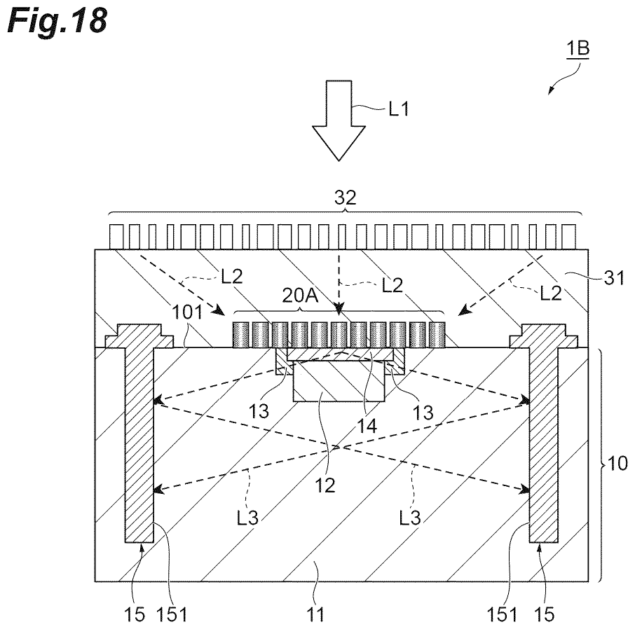

FIG. 17 is a cross-sectional view showing a configuration of an optical element 1A according to a reference example. The optical element 1A has the same configuration as the optical element 1 of the present embodiment, except that the nanostructure 20 is not provided. In the optical element 1A, the convergent light L2 emitted from the meta-lens 32 is incident on the APD 10. In this case, an aperture ratio can be improved, and an avalanche probability can be increased by focusing light within the light-receiving region. However, the optical path in the light-receiving region of the APD 10 is short, and particularly when the wavelength of the light L1 is a long wavelength such as in the infrared region, the quantum efficiency is suppressed to a low level. FIG. 18 is a cross-sectional view showing a configuration of an optical element 1B according to another reference example. The optical element 1B has a structure in which a nanostructure 20A is further provided in the optical element 1A described above. The nanostructure 20A is provided on the light-incidence surface 101 of the APD 10. The nanostructure 20A, unlike the nanostructure 20 of the present embodiment, does not individually modulate the phase for each unit structure 201, and thus does not have a function of focusing the diffracted light L3. In that case, although the optical path in the light-receiving region of the APD 10 can be lengthened by the diffracted light L3, the avalanche probability is suppressed to a low level because the diffracted light L3 is not focused. The optical element 1 of the present embodiment overcomes the disadvantages of the optical elements 1A and 1B, and can improve all of the aperture ratio, the avalanche probability, and the quantum efficiency of photoelectric conversion.

As in the present embodiment, the optical element 1 may include the meta-lens 32. By causing the convergent light L2 to be incident on the nanostructure 20 via the meta-lens 32, an aperture ratio can be increased to increase an amount of light incident on the APD 10. Therefore, a light receiving sensitivity of the optical element 1 can be increased.

As in the present embodiment, the light-focusing structure may further include the reflecting portion 15. In this case, at least a part of the diffracted light L3 from the nanostructure 20 is collected at a focal point R after being reflected by the light reflecting surface 151. Thereby, an optical path in the light-receiving region can be further lengthened to further increase a quantum efficiency of photoelectric conversion.

The light-focusing structure may focus the diffracted light L3 by individually modulating a phase of ±2nd or higher order (that is, n≥2) diffracted light L3 in each unit structure 201. The larger the order of the diffracted light L3 emitted from the nanostructure 20, the larger the inclination of the propagation direction of the diffracted light L3 with respect to a normal direction of the light-incidence surface 101. According to this optical element 1, the inclination of the propagation direction of the diffracted light L3 can be further increased to further lengthen an optical path in the light-receiving region, and to further increase a quantum efficiency of photoelectric conversion.

As in the present embodiment, a phase distribution of the diffracted light L3 emitted from the nanostructure 20 may satisfy the mathematical formula (1) described above. With such a configuration, for example, the nanostructure 20 can focus the diffracted light L3.

As in the present embodiment, each unit structure 201 may have the slit 22 extending in a predetermined direction. Then, a relative position of a center line A2 of the slit 22 of each unit structure 201 with respect to a center line A1 of each unit structure 201 in a direction intersecting the predetermined direction may be determined according to the phase. With such a configuration, for example, the phase of the diffracted light L3 can be individually modulated in each unit structure 201.

As described above, the plurality of unit structures 201 may mainly comprise metal. In this case, by plasmonic diffraction, an inclination of a propagation direction of the diffracted light L3 can be further increased to further lengthen an optical path in the light-receiving region, and to further increase a quantum efficiency of photoelectric conversion.

As described above, the plurality of unit structures 201 may mainly comprise dielectric material. Even in this case, by causing the nanostructure 20 to emit ±n-th order diffracted light L3, the effects of the present embodiment described above can be obtained.

### First Modification

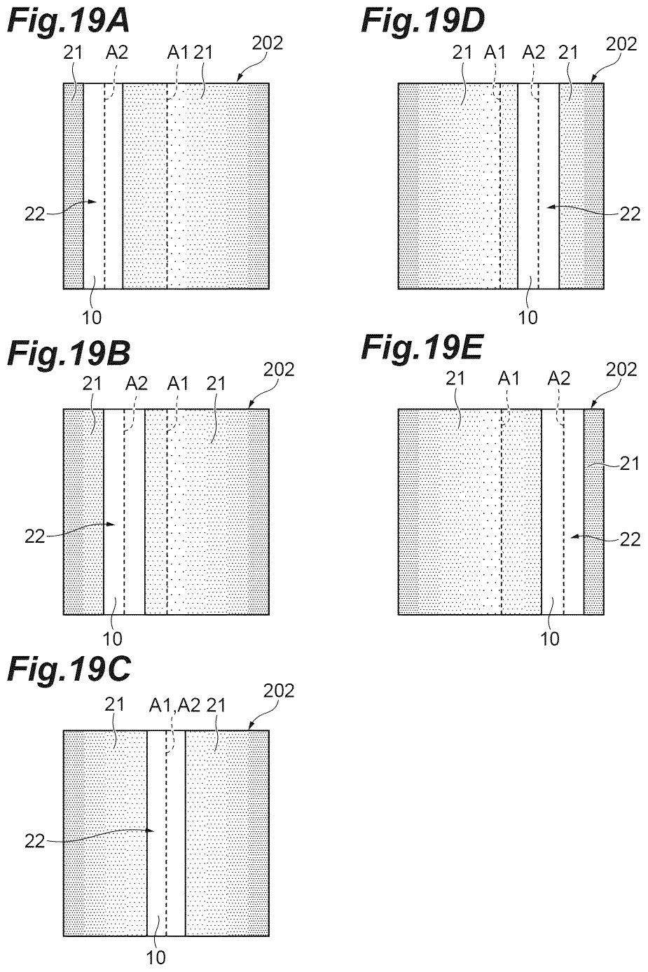

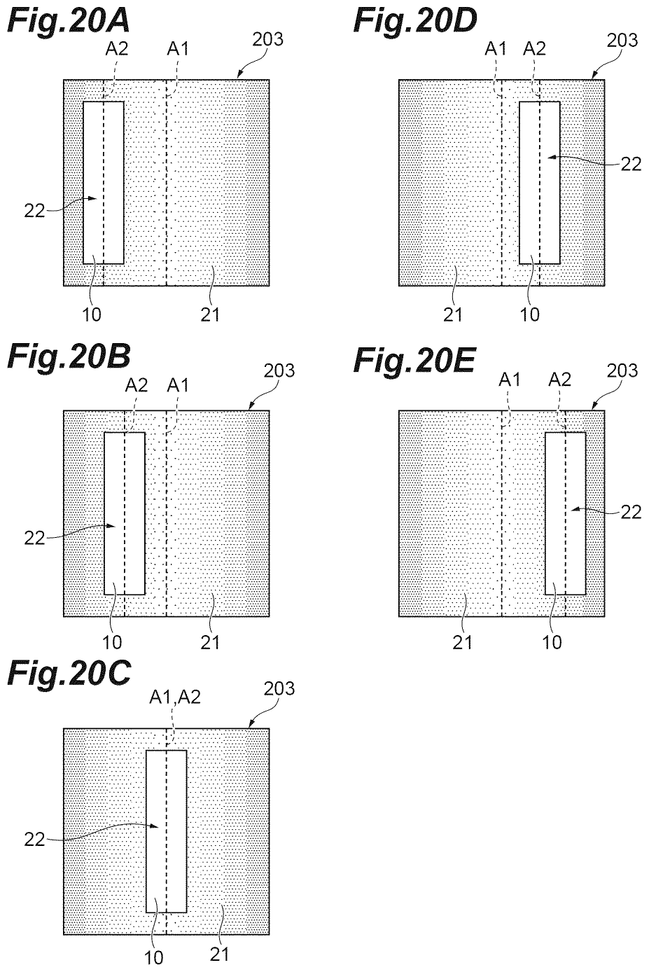

FIGS. 19A to 19E, FIGS. 20A to 20E, FIGS. 21A to 21E, FIGS. 22A to 22E, and FIGS. 23A to 23E are plan views showing unit structures 202 to 206 (first unit structures) according to a modification of the above embodiment. In the unit structure 202 shown in FIGS. 19A to 19E, a pair of films 21 reach both ends of the unit structure 202 in an extending direction (predetermined direction) of the slit 22, and are connected to a pair of films 21 of an adjacent unit structure 202 in the predetermined direction, respectively. In the unit structure 203 shown in FIGS. 20A to 20E, a pair of films 21 are connected to each other at both ends of the slit 22 in an extending direction of the slit 22, and the slit 22 is surrounded by the film 21. Also in the unit structures 202 and 203 shown in FIGS. 19A to 19E and FIGS. 20A to 20E, a relative position of a center line A2 of the slit 22 with respect to a center line A1 of the unit structure is individually set for each unit structure. Then, a phase of the diffracted light L3 changes according to the relative position of the center line A2 of the slit 22 with respect to the center line A1 of the unit structure.

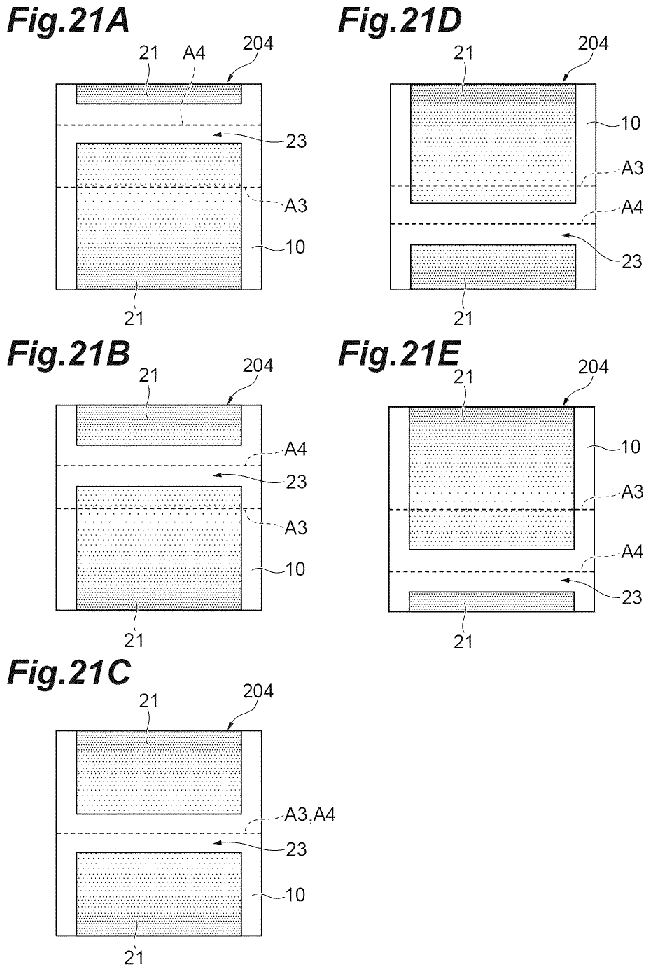

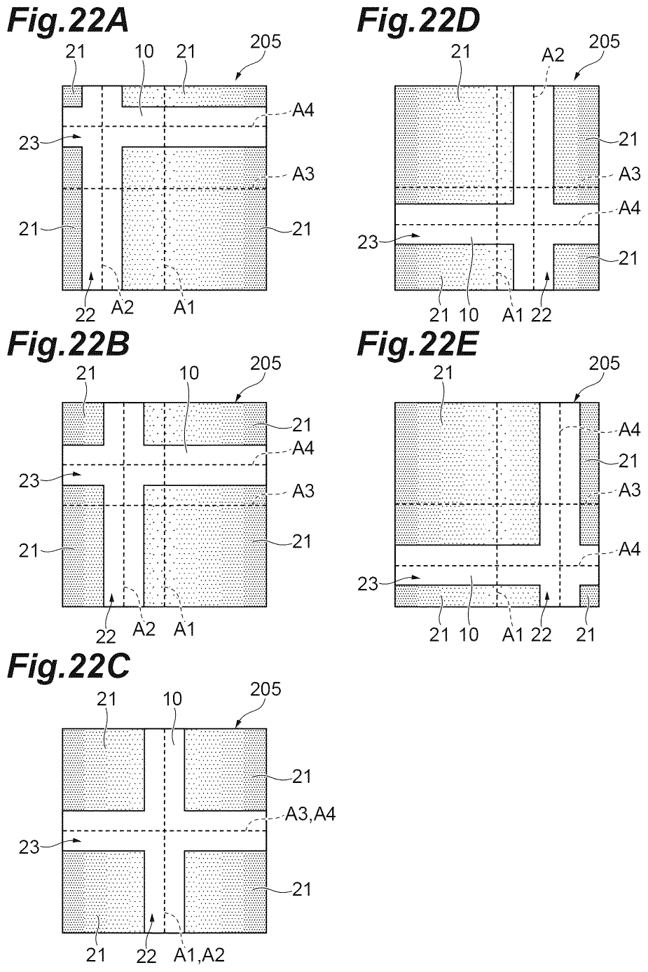

The unit structure 204 shown in FIGS. 21A to 21E has a slit 23 instead of the slit 22 described above. The slit 23 extends in a direction intersecting (for example, orthogonal to) the extending direction of the slit 22 of the above embodiment. In this way, an extending direction of the slit in the nanostructure 20 can be arbitrarily determined. Therefore, a polarization plane of the diffracted light L3 diffracted and focused by the nanostructure 20 can also be arbitrarily determined. In the unit structure 204 shown in FIGS. 21A to 21E, a relative position of a center line A4 of the slit 23 with respect to a center line A3 of the unit structure 204 is individually set for each unit structure 204. Then, a phase of the diffracted light L3 changes according to the relative position of the center line A4 of the slit 23 with respect to the center line A3 of the unit structure 204. As shown in FIGS. 22A to 22E, the unit structure 205 may have both of the two slits 22 and 23. In this case, a phase of each polarization component can be individually controlled, and circularly polarized, elliptically polarized, or non-polarized (unpolarized) light can be diffracted and focused.

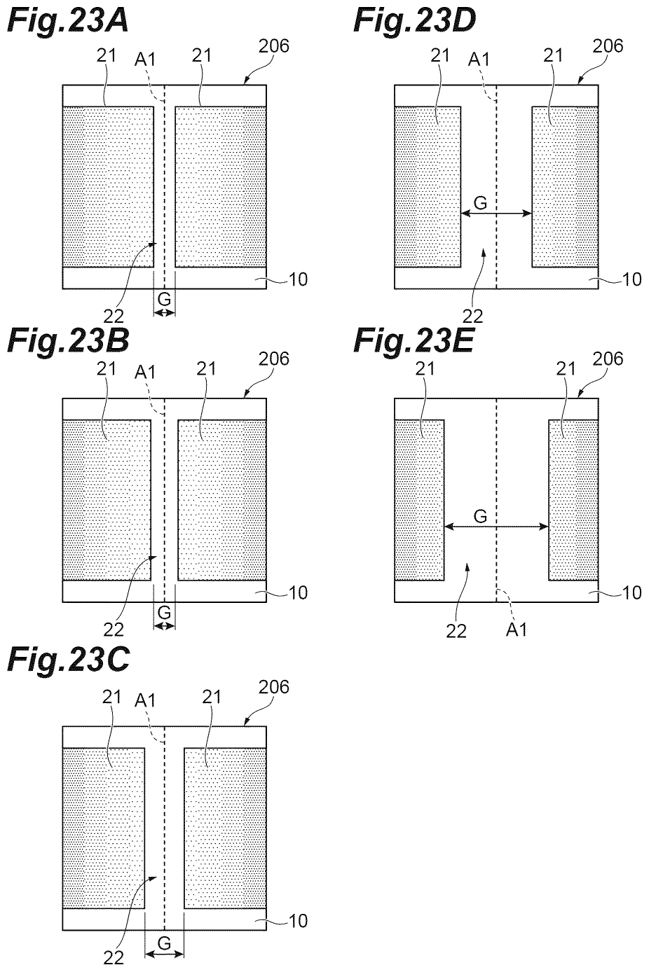

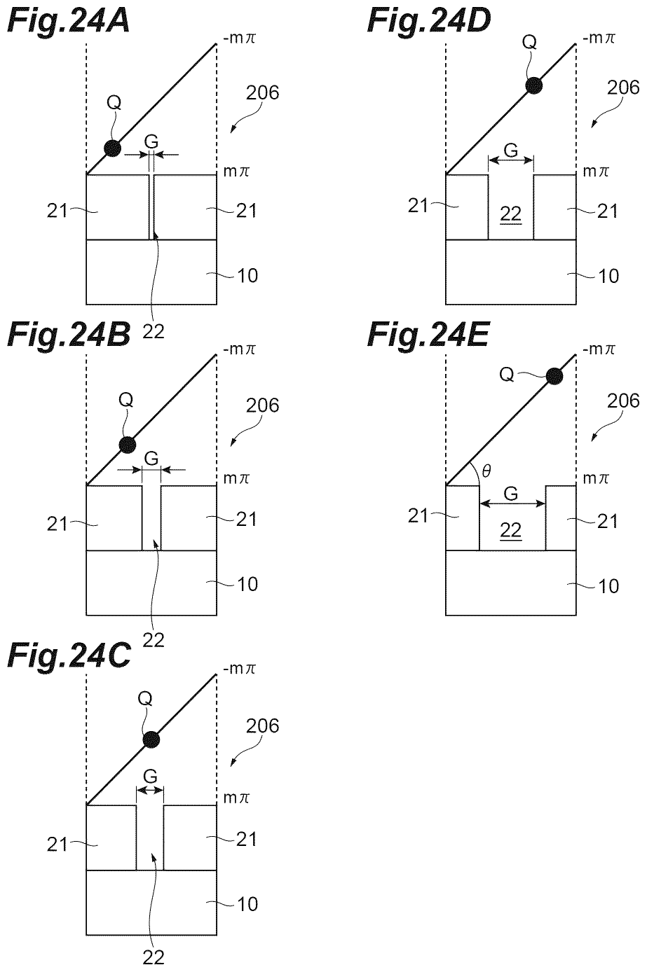

FIGS. 24A to 24E are side views of a unit structure 206, corresponding to FIGS. 23A to 23E, respectively. In the unit structure 206 shown in FIGS. 23A to 23E and FIGS. 24A to 24E, unlike the above embodiment, in all the unit structures 206, a center line of the slit 22 coincides with a center line A1 of the unit structure 206. Then, a size of a width G of the slit 22 is individually set for each unit structure 206. In this case, a phase of the diffracted light L3 changes according to the size of the width G of the slit 22. A point Q in FIGS. 24A to 24E indicates a magnitude of the phase of the diffracted light L3 (mπ (rad) to −mπ (rad), where m is an integer of 1 or more) corresponding to the size of the width G of the slit 22. In the examples shown in FIGS. 24A to 24E, the smaller the width G of the slit 22, the larger the phase of the diffracted light L3, and the larger the width G of the slit 22, the smaller the phase of the diffracted light L3. A diffraction angle θ is also shown in FIG. 24E.

### Second Modification

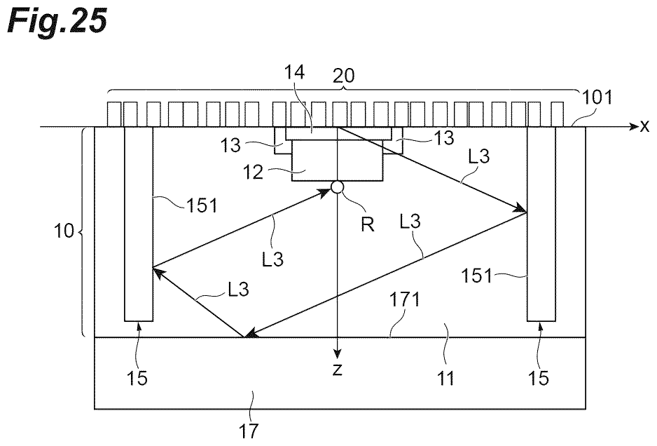

FIG. 25 is a diagram schematically showing a configuration according to a modification of the above embodiment. As shown in FIG. 25, the light-focusing structure may further include a reflecting portion 17 (second reflecting portion). The reflecting portion 17 is provided on a side opposite to the nanostructure 20 with respect to the light-incidence surface 101. The APD 10 is located between the light-incidence surface 101 and the reflecting portion 17. The reflecting portion 17 has a light reflecting surface 171 (second light reflecting surface) facing toward the light-incidence surface 101. In one example, the light reflecting surface 171 is parallel to the light-incidence surface 101. The reflecting portion 17 may be, for example, a metal mirror, or may be a metal wiring provided on a circuit board.

In this modification, the diffracted light L3 emitted from the nanostructure 20 is reflected at the light reflecting surface 151 of the reflecting portion 15, then further reflected at the light reflecting surface 171 of the reflecting portion 17, and further reflected at the light reflecting surface 151 opposite to the light reflecting surface 151 at which the previous reflection occurred, and reaches a focal point R. In this way, at least a part of the diffracted light L3 from the nanostructure 20 is collected at the focal point R after being reflected by the light reflecting surface 171. Thereby, an optical path in the light-receiving region of the APD 10 can be further lengthened to further increase a quantum efficiency of photoelectric conversion.

### Third Modification

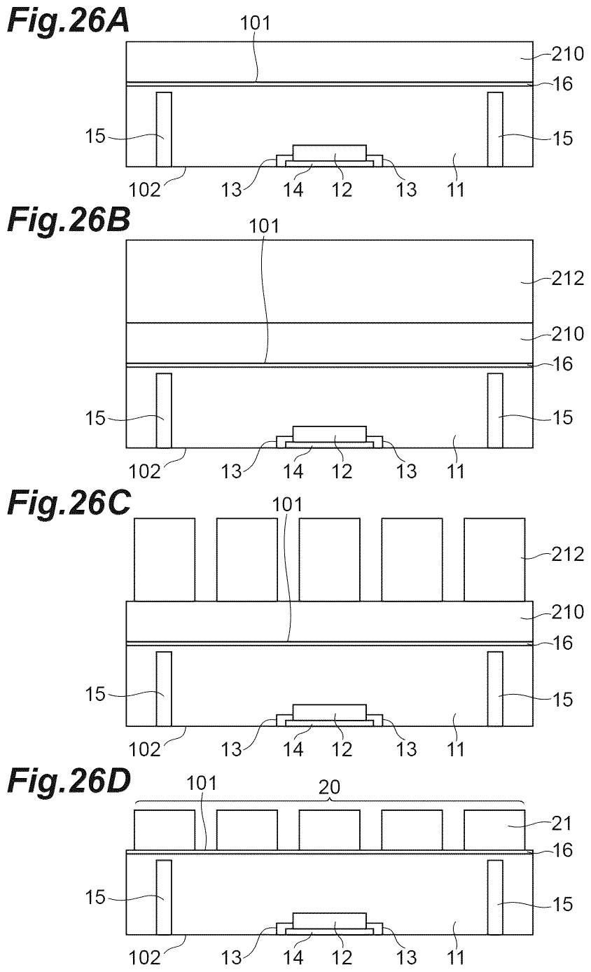

FIGS. 26A to 26D are diagrams showing a manufacturing process of the nanostructure 20. As shown in FIG. 26D, in this example, the semiconductor regions 12 to 14 are arranged closer to a back surface 102 of the APD 10. The semiconductor region 14 constitutes a part of the back surface 102. The semiconductor region 11 constitutes the entire light-incidence surface 101. Other structures are the same as in the above embodiment. The nanostructure 20 of the above embodiment can also be manufactured by the same process as in this modification.

As shown in FIG. 26A, first, an anti-reflection film 16 (for example, an SiO₂ film) is deposited on the light-incidence surface 101 by, for example, sputtering. At this time, a film thickness is, for example, 2 nm, and including a thickness of a natural oxide film, a thickness of the anti-reflection film 16 is, for example, 5 nm. Next, a film 210 composed of a material of the film 21 (for example, amorphous silicon) is formed on the anti-reflection film 16 by, for example, sputtering. A thickness of the film 210 is, for example, 200 nm. Next, as shown in FIG. 26B, an electron beam resist 212 is applied on the film 210. A thickness of the electron beam resist 212 is, for example, 300 nm. As the electron beam resist 212, for example, ZEP520A (manufactured by Zeon Corporation) is used. Next, as shown in FIG. 26C, patterning with electron beam and development are performed on the electron beam resist 212. Thereafter, as shown in FIG. 26D, dry etching is performed on the film 210 while using the electron beam resist 212 as an etching mask. At this time, etching is performed until the anti-reflection film 16 is exposed. The anti-reflection film 16 functions as an etching stop layer. In this way, the nanostructure 20 having the plurality of films 21 arranged along the light-incidence surface 101 is formed.

### Fourth Modification

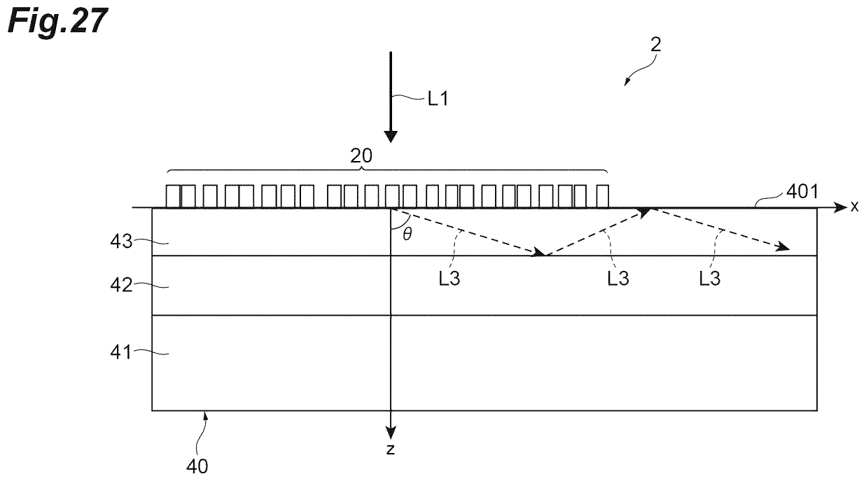

FIG. 27 is a diagram schematically showing a cross-sectional configuration of an optical element 2 according to a modification of the above embodiment. The optical element 2 includes the nanostructure 20 and an optical integrated circuit 40 as an optical component. The nanostructure 20 is provided on a light-incidence surface 401 which is a surface of the optical integrated circuit 40. The optical integrated circuit 40 is an SOI (Silicon On Insulator) substrate, and includes a first Si layer 41, an SiO₂ layer 42, and a second Si layer 43. The SiO₂ layer 42 is provided on the first Si layer 41, and the second Si layer 43 is provided on the SiO₂ layer 42. A refractive index of the SiO₂ layer 42 is smaller than refractive indices of the first Si layer 41 and the second Si layer 43. The second Si layer 43 constitutes the light-incidence surface 401.

In this modification, the diffracted light L3 emitted from the nanostructure 20 at a diffraction angle θ is incident on the second Si layer 43 and propagates in the second Si layer 43. At this time, since the optical integrated circuit 40 does not include the reflecting portion 15, a form of light focusing by the nanostructure 20 is the form shown in FIG. 11. Also in this modification, a propagation direction of emitted light (diffracted light L3) from the nanostructure 20 can be largely inclined from a normal direction of the light-incidence surface 401, as compared with a conventional meta-lens. Therefore, the diffracted light L3 can be easily confined in the thin second Si layer 43. In the illustrated example, the light L1 is incident on the nanostructure 20, but similarly to the above embodiment, the meta-lens 32 may be provided above the nanostructure 20, and the convergent light L2 may be incident on the nanostructure 20. In this modification, the nanostructure 20 focuses the diffracted light L3 into the inside of the optical integrated circuit 40, but the diffracted light L3 may be focused into an inside of an optical component different from the optical integrated circuit 40, provided alongside the optical integrated circuit 40.

### First Example

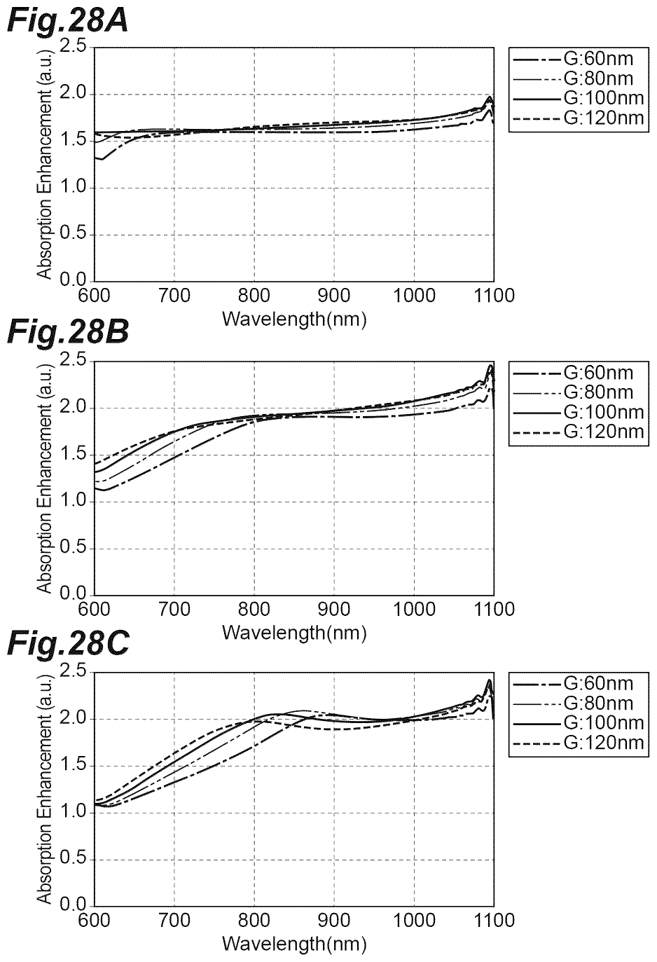

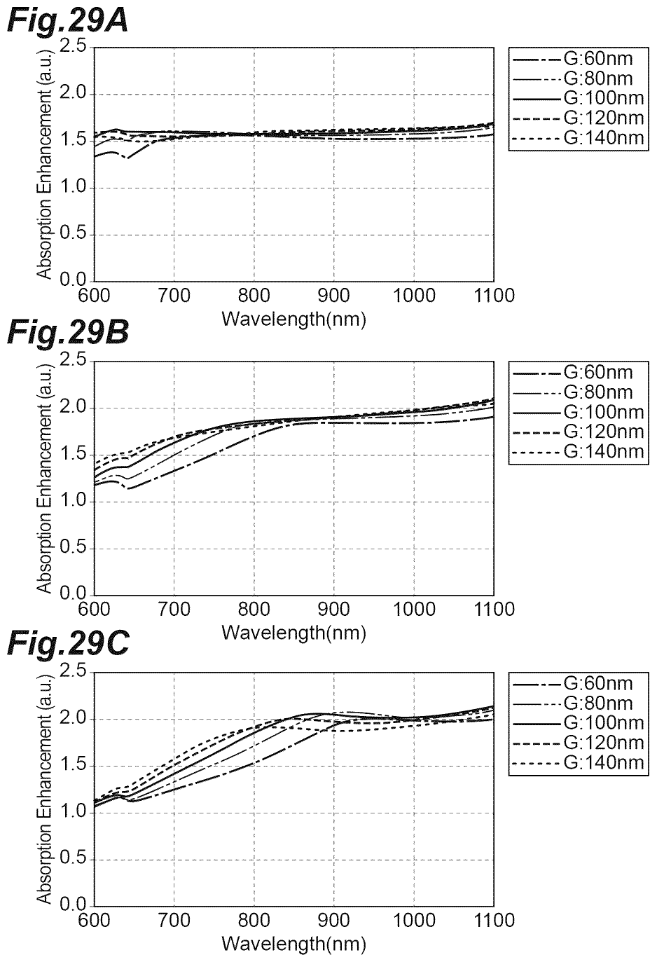

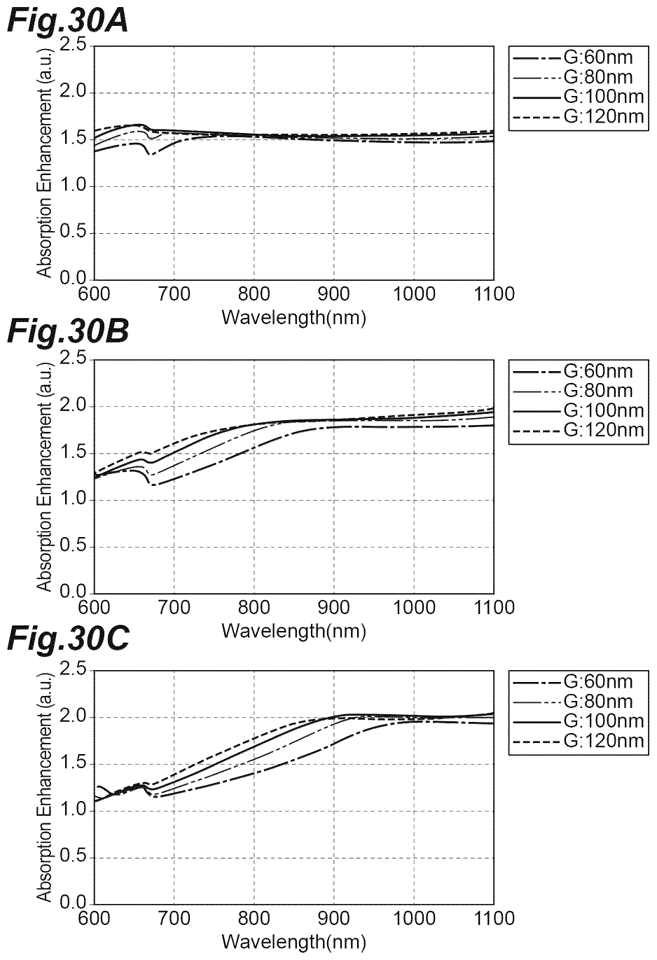

A structure of the unit structure 201 was examined by simulation in a case where the film 21 is composed of silicon (Si) and the anti-reflection film 16 is not provided. In this simulation, a size of a width G of the slit 22 was set to each of 60 nm, 80 nm, 100 nm, and 120 nm, a period P was set to each of 310 nm, 330 nm, and 350 nm, and a height H of the film 21 was set to each of 100 nm, 150 nm, and 200 nm. FIGS. 28A to 28C, FIGS. 29A to 29C, and FIGS. 30A to 30C are graphs showing a relationship between a wavelength and a light absorption enhancement factor in this simulation. A value of the light absorption enhancement factor is a normalized value with a case where the nanostructure 20 is not provided being 1. FIGS. 28A to 28C show a case where the period P is 310 nm. FIGS. 29A to 29C show a case where the period P is 330 nm. FIGS. 30A to 30C show a case where the period P is 350 nm. FIGS. 28A, 29A, and 30A show a case where the height H of the film 21 is 100 nm, FIGS. 28B, 29B, and 30B show a case where the height H of the film 21 is 150 nm, and FIGS. 28C, 29C, and 30C show a case where the height H of the film 21 is 200 nm. From these graphs, it can be seen that the light absorption enhancement factor can be controlled by setting structural parameters such as the period P, the height H, and the width G. If the unit structure 201 has, for example, the structural parameters of this simulation, the effects of the above embodiment can be obtained. The height H of the film 21 may be in a range of 100 nm to 500 nm, and the width G of the slit 22 may be in a range of 60 nm to 200 nm.

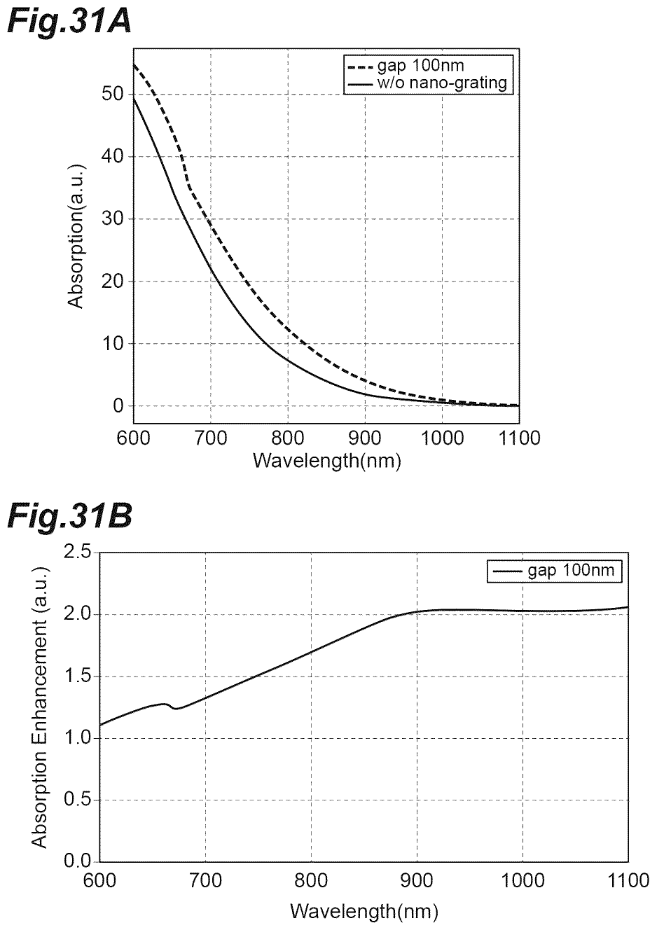

FIG. 31A is a graph showing a relationship between a wavelength and light absorption of the APD 10 in this simulation. In this graph, the height H of the film 21 is 200 nm, the size of the width G of the slit 22 is 100 nm, and the period P is 350 nm. In FIG. 31A, a dashed line indicates a case where the nanostructure 20 is provided, and a solid line indicates a case where the nanostructure 20 is not provided. As shown in FIG. 31A, the light absorption of the APD 10 varies according to the wavelength of the incident light, but, over the entire wavelength range, the light absorption of the APD 10 is larger than in the case where the nanostructure 20 is not provided. FIG. 31B is a graph showing a relationship between a wavelength and a light absorption enhancement factor in this simulation. A value of the light absorption enhancement factor is a normalized value with a case where the nanostructure 20 is not provided being 1. As shown in FIG. 31B, when the film 21 is composed of silicon (Si), it is possible to improve a sensitivity of the optical element 1 over a broad wavelength range.

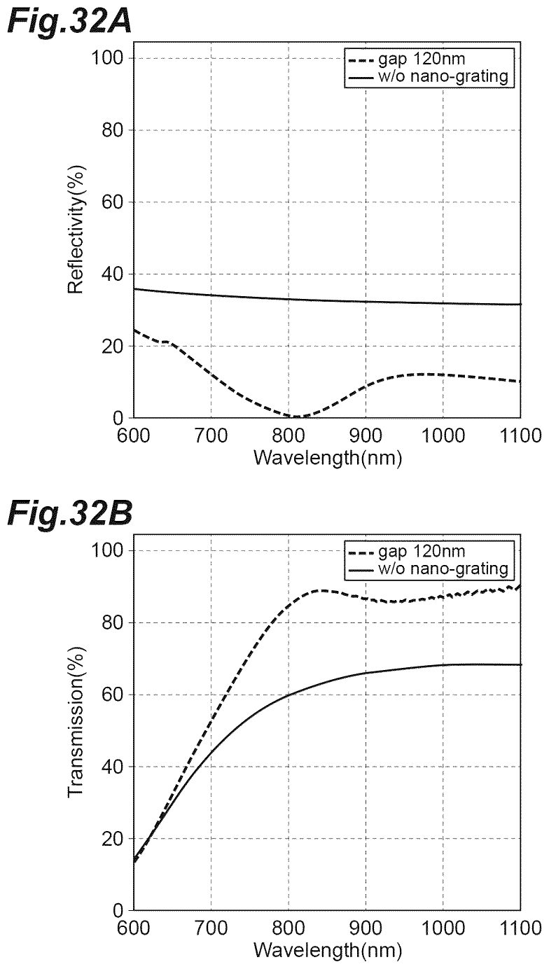

FIG. 32A is a graph showing a relationship between a wavelength and a reflectance of the nanostructure 20 in a certain structure of this simulation. FIG. 32B is a graph showing a relationship between a wavelength and a transmittance of the nanostructure 20 in a certain structure of this simulation. In the figures, a dashed line indicates a case where the nanostructure 20 is provided, and a solid line indicates a case where the nanostructure 20 is not provided. As shown in FIGS. 32A and 32B, the reflectance and transmittance of the nanostructure 20 vary according to the wavelength of the incident light, but when the nanostructure 20 is provided, the reflectance is smaller and the transmittance is larger than in the case where the nanostructure 20 is not provided over the entire wavelength range. Therefore, by selecting structural parameters, the nanostructure 20 can also function as an anti-reflection film.

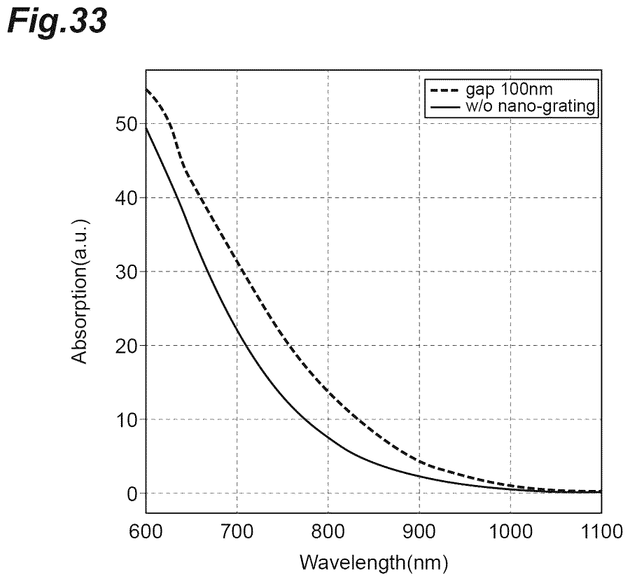

FIG. 33 is a graph showing a relationship between a wavelength and light absorption of the APD 10 in a certain structure of this simulation. In FIG. 33, a dashed line indicates a case where the nanostructure 20 is provided, and a solid line indicates a case where the nanostructure 20 is not provided. As shown in FIG. 33, the light absorption of the APD 10 varies according to the wavelength of the incident light, but when the nanostructure 20 is provided, the light absorption of the APD 10 is larger than in the case where the nanostructure 20 is not provided over the entire wavelength range.

### Second Example

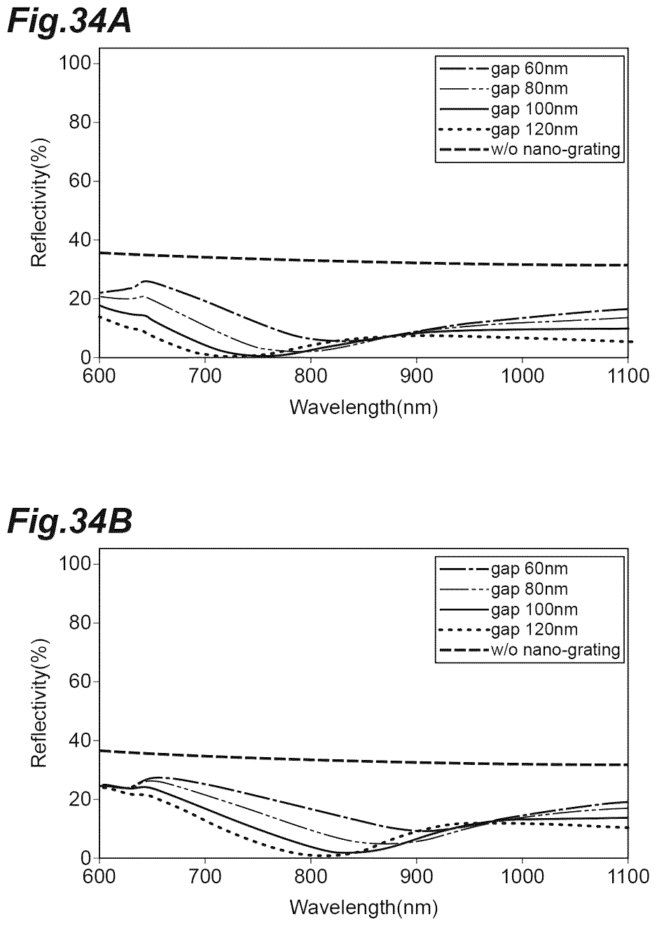

A structure of the unit structure 201 was examined by simulation in a case where the film 21 is composed of silicon (Si) and an anti-reflection film 16 composed of an SiO₂ film or an Al₂O₃ film is provided. FIGS. 34A and 34B are graphs showing a relationship between a wavelength and a reflectance in this simulation. In this simulation, a size of a width G of the slit 22 was set to each of 60 nm, 80 nm, 100 nm, and 120 nm, and a period P was set to 350 nm. FIG. 34A is a graph for a case where a height H of the film 21 is 150 nm. FIG. 34B is a graph for a case where the height H of the film 21 is 200 nm. For comparison, a curve (w/o nano-grating) for a case where the nanostructure 20 is not provided is also shown in these figures. As shown in FIGS. 34A and 34B, even when the anti-reflection film 16 is provided, the reflectance can be reduced over a broad wavelength range to improve a sensitivity of the optical element 1.

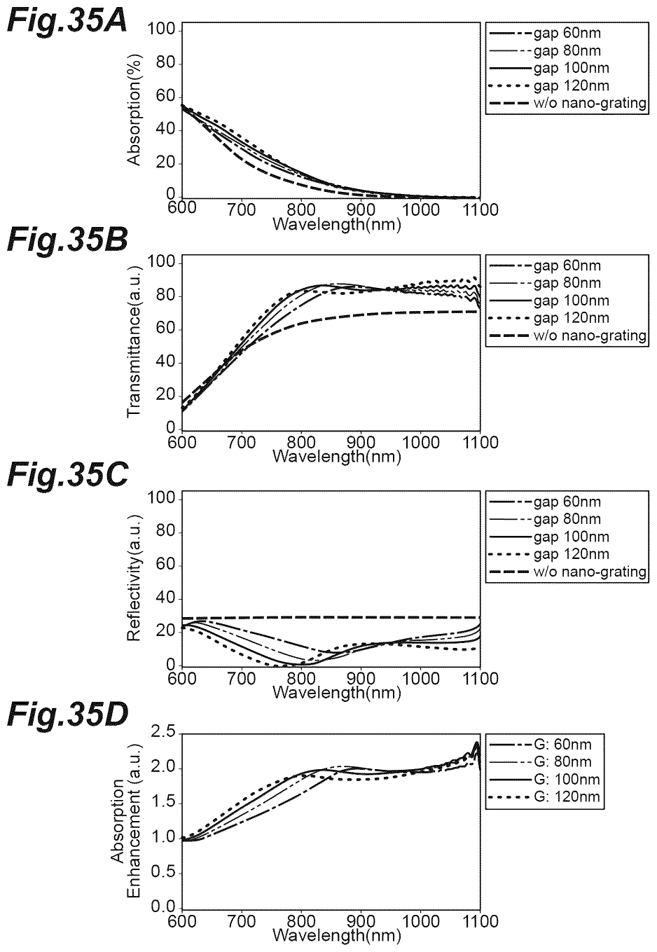

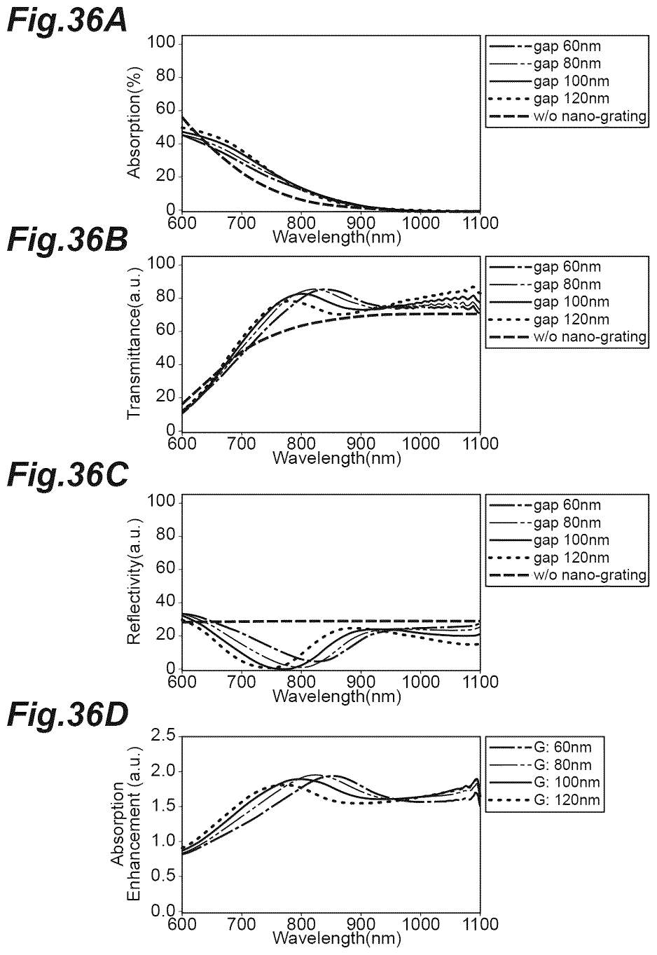

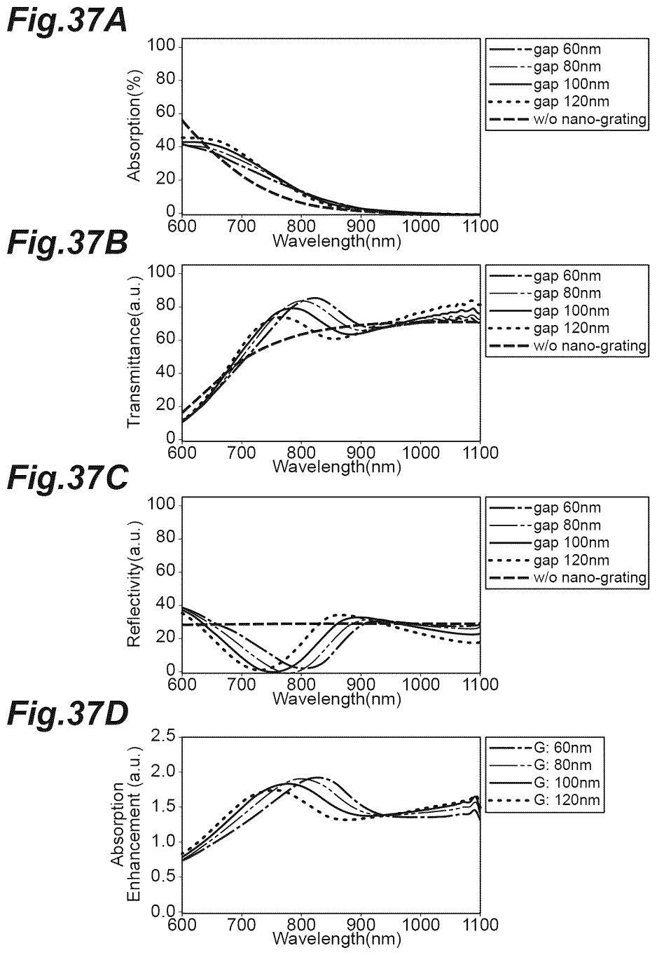

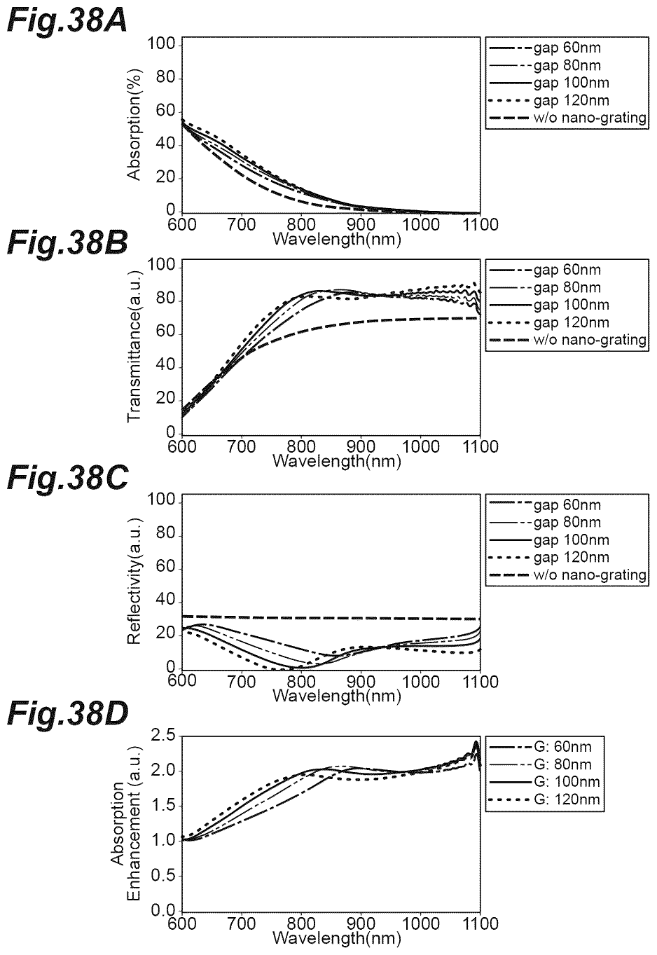

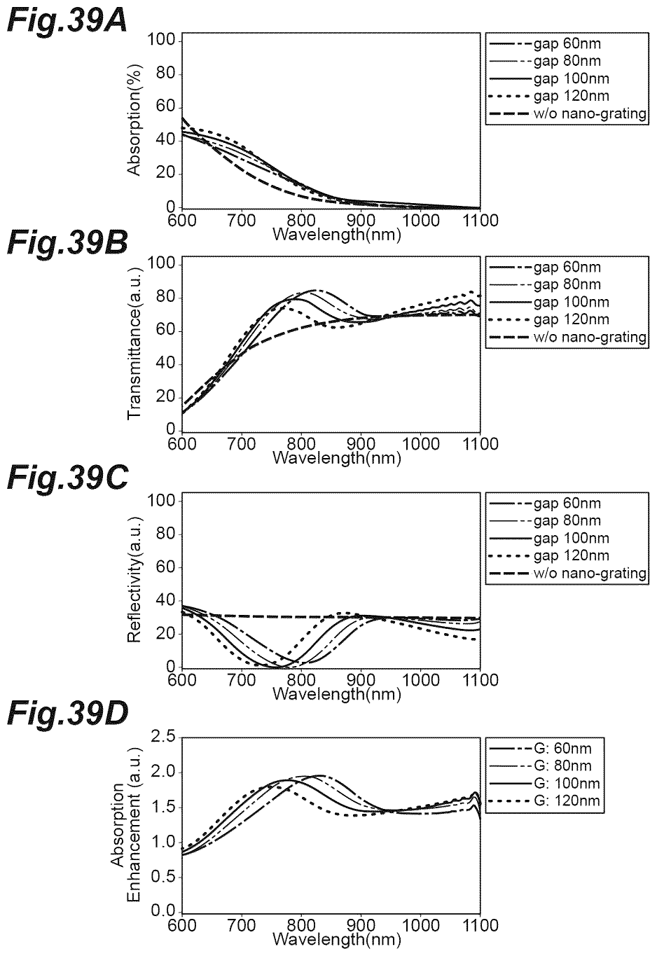

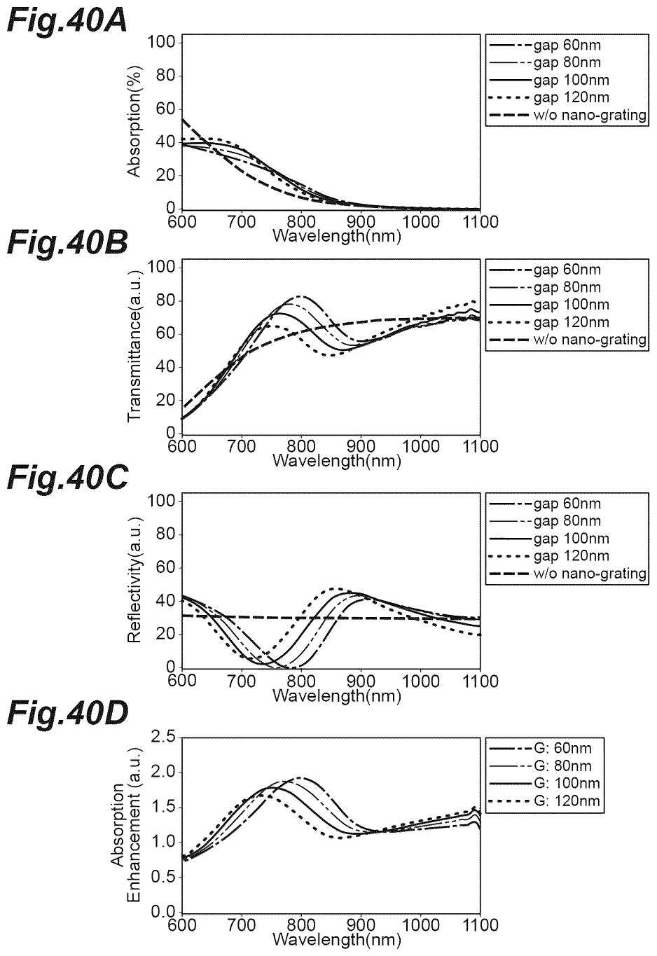

FIGS. 35A to 35D, 36A to 36D, 37A to 37D, 38A to 38D, 39A to 39D, and 40A to 40D are graphs showing simulation results in a case where the film 21 is composed of silicon (Si) and the anti-reflection film 16 is provided. In this simulation, the period P was set to 310 nm, the height H of the film 21 was set to 200 nm, the size of the width G of the slit 22 was set to each of 60 nm, 80 nm, 100 nm, and 120 nm, and a thickness of the anti-reflection film 16 was set to each of 0 nm, 5 nm, and 10 nm. FIGS. 35A to 35D, FIGS. 36A to 36D, and 37A to 37D show a case where the anti-reflection film 16 is composed of an Al₂O₃ film. FIGS. 38A to 38D, 39A to 39D, and 40A to 40D show a case where the anti-reflection film 16 is composed of an SiO₂ film. FIGS. 35A to 35D and 38A to 38D show a case where the thickness of the anti-reflection film 16 is 0 nm. FIGS. 36A to 36D and 39A to 39D show a case where the thickness of the anti-reflection film 16 is 5 nm. FIGS. 37A to 37D and 40A to 40D show a case where the thickness of the anti-reflection film 16 is 10 nm. FIGS. 35A, 36A, 37A, 38A, 39A, and 40A show a relationship between a wavelength and light absorption of the APD 10, FIGS. 35B, 36B, 37B, 38B, 39B, and 40B show a relationship between a wavelength and a transmittance of the nanostructure 20, FIGS. 35C, 36C, 37C, 38C, 39C, and 40C show a relationship between a wavelength and a reflectance of the nanostructure 20, and FIGS. 35D, 36D, 37D, 38D, 39D, and 40D show a relationship between a wavelength and a light absorption enhancement factor of the APD 10. For comparison, a curve (w/o nano-grating) for a case where the nanostructure 20 is not provided is also shown in these figures. A value of the light absorption enhancement factor is a normalized value with a case where the nanostructure 20 is not provided being 1. In any of the graphs, it can be seen that when the nanostructure 20 is provided, a sensitivity of the optical element 1 can be improved as compared with a case where the nanostructure 20 is not provided.

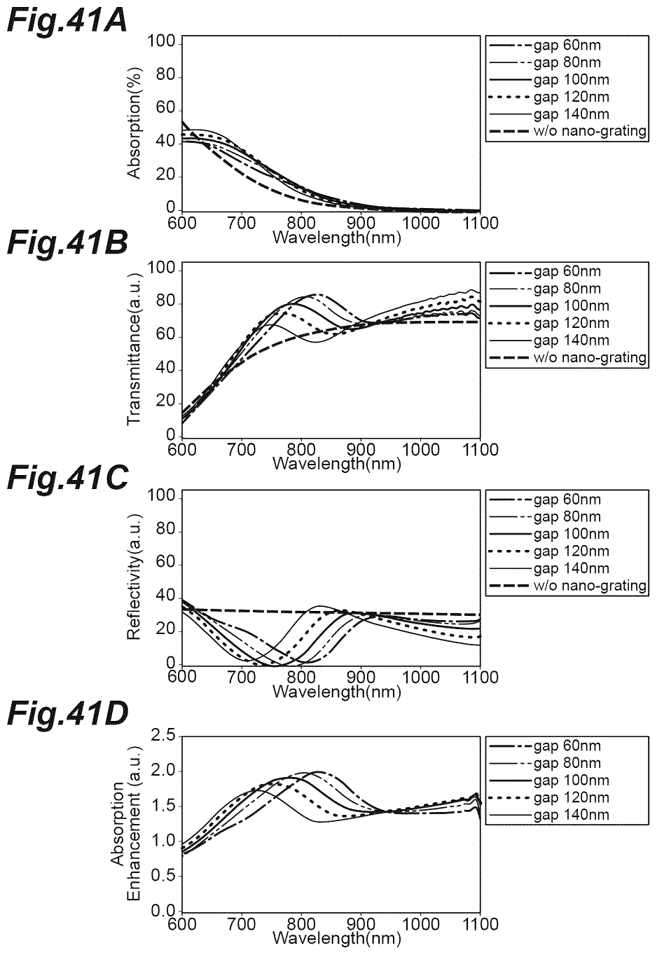

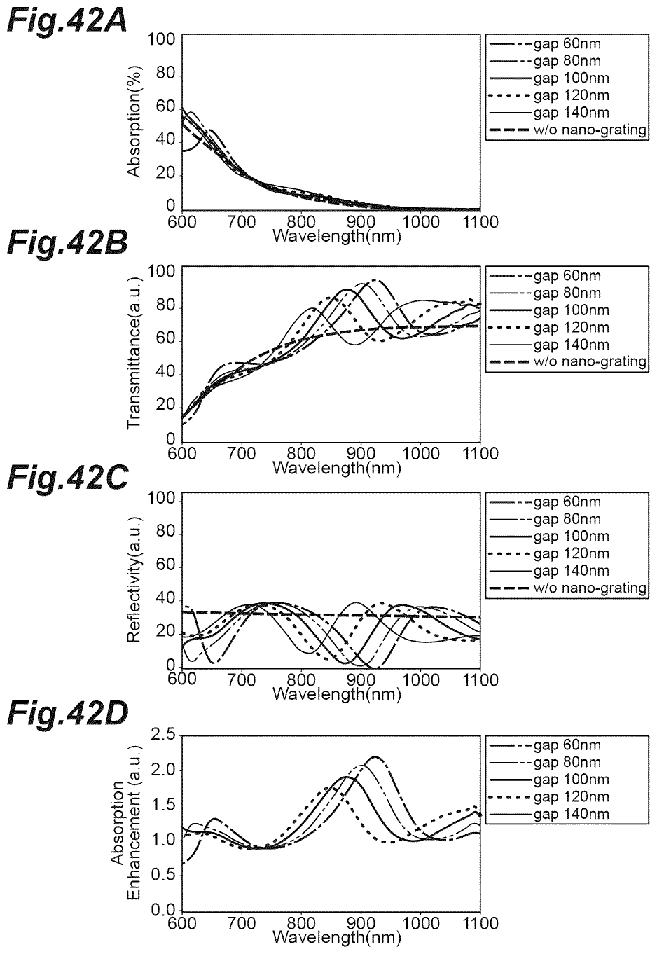

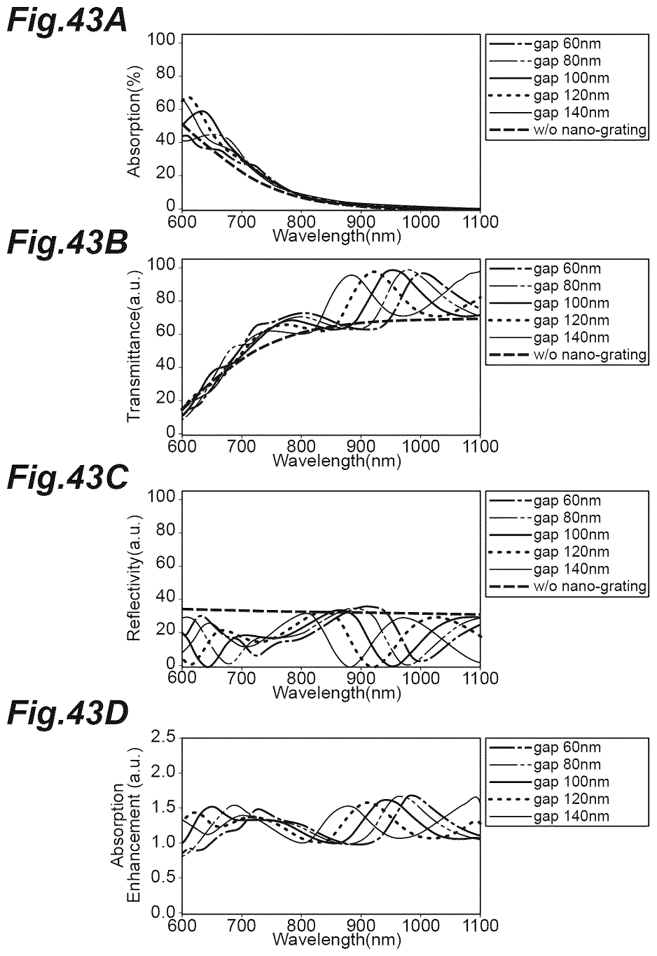

FIGS. 41A to 41D, 42A to 42D, and 43A to 43D are graphs showing simulation results in a case where the film 21 is composed of silicon (Si), and the anti-reflection film 16 is composed of an SiO₂ film (thickness 2 nm) provided on the APD 10 and an Al₂O₃ film (thickness 10 nm) provided on the SiO₂ film. In this simulation, the period P was 310 nm, the height H of the film 21 was set to each of 200 nm, 300 nm, and 400 nm, and the size of the width G of the slit 22 was set to each of 60 nm, 80 nm, 100 nm, 120 nm, and 140 nm. FIGS. 41A to 41D show a case where the height H of the film 21 is 200 nm. FIGS. 42A to 42D show a case where the height H of the film 21 is 300 nm. FIGS. 43A to 43D show a case where the height H of the film 21 is 400 nm. FIGS. 41A, 42A, and 43A show a relationship between a wavelength and light absorption of the APD 10. FIGS. 41B, 42B, and 43B show a relationship between a wavelength and a transmittance of the nanostructure 20. FIGS. 41C, 42C, and 43C show a relationship between a wavelength and a reflectance of the nanostructure 20. FIGS. 41D, 42D, and 43D show a relationship between a wavelength and a light absorption enhancement factor of the APD 10. For comparison, a curve (w/o nano-grating) for a case where the nanostructure 20 is not provided is also shown in these figures. A value of the light absorption enhancement factor is a normalized value with a case where the nanostructure 20 is not provided being 1. In any of the graphs, it can be seen that when the nanostructure 20 is provided, a sensitivity of the optical element 1 can be improved as compared with a case where the nanostructure 20 is not provided. By including both the SiO₂ film and the Al₂O₃ film in the anti-reflection film 16, an etching resistance of the anti-reflection film 16 can be improved, and an etching selectivity with respect to the film 21 can be further increased.

### Third Example

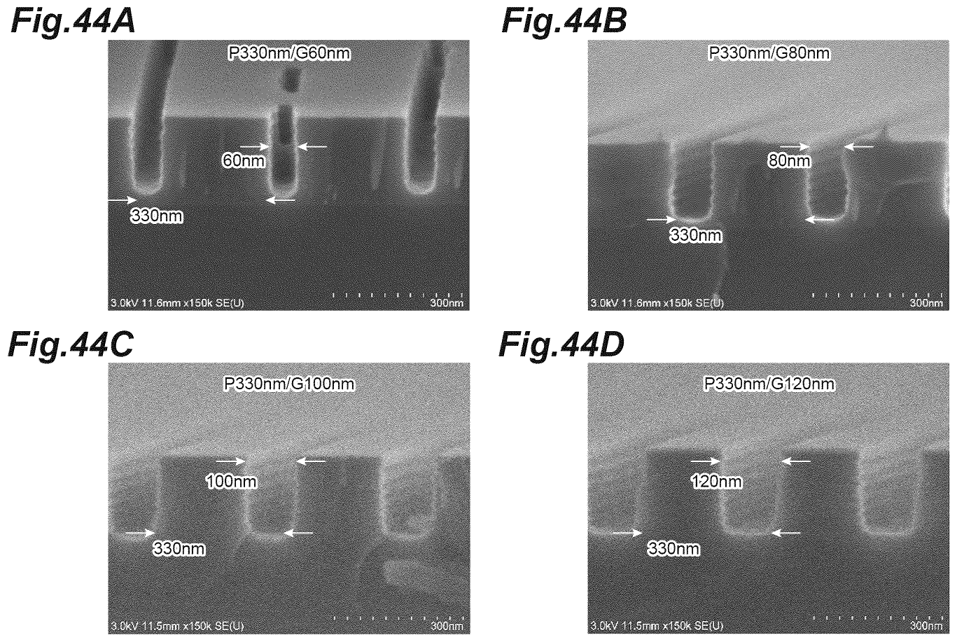

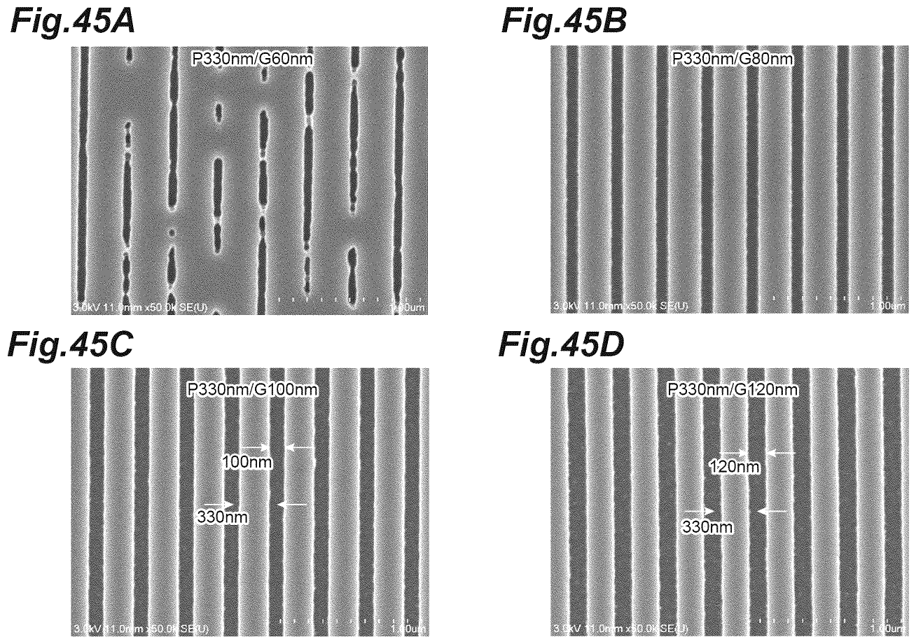

FIGS. 44A to 44D are optical microscope images showing the nanostructure 20. FIGS. 45A to 45D are scanning electron microscope (SEM) images showing the nanostructure 20 fabricated by the method of this modification. In these nanostructures 20, a period P is 330 nm, and a height H of the film 21 is 200 nm. FIGS. 44A and 45A show a case where a size of a width G of the slit 22 is 60 nm. FIGS. 44B and 45B show a case where the size of the width G of the slit 22 is 80 nm. FIGS. 44C and 45C show a case where the size of the width G of the slit 22 is 100 nm. FIGS. 44D and 45D show a case where the size of the width G of the slit 22 is 120 nm. The nanostructures 20 shown in these figures can be suitably fabricated by, for example, the method described in the third modification.

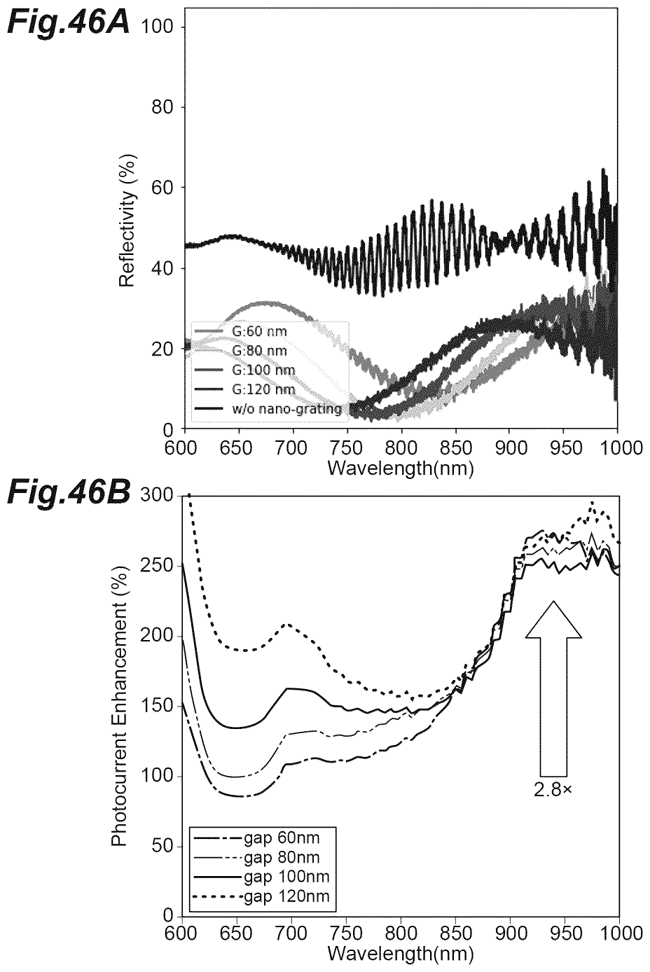

FIG. 46A is a graph showing a relationship between a wavelength and a reflectance of the fabricated nanostructure 20. FIG. 46B is a graph showing a relationship between a wavelength and a photocurrent enhancement factor of the APD 10 of an optical element having the fabricated nanostructure 20. A value of the photocurrent enhancement factor is a normalized value with a case where the nanostructure 20 is not provided being 100%. A period P of the nanostructure 20 is 310 nm, a height H of the film 21 is 200 nm, and a size of a width G of the slit 22 is each of 60 nm, 80 nm, 100 nm, and 120 nm. For comparison, a curve (w/o nano-grating) for a case where the nanostructure 20 is not provided is also shown in FIG. 46A. As shown in FIG. 46A, according to the fabricated nanostructure 20, the reflectance can be reduced over a broad wavelength range to improve a sensitivity of the optical element. As shown in FIG. 46B, by providing the nanostructure 20, a sensitivity of the optical element can be improved as compared with a case where the nanostructure 20 is not provided. In particular, in a wavelength band of 900 nm or more, a value of the photocurrent enhancement factor can be increased to 2.8 times or more with respect to a case where the nanostructure 20 is not provided as a reference.

The optical element according to the present disclosure is not limited to the embodiments and modifications described above, and various other modifications are possible. For example, in the above embodiments and modifications, the APD and the optical integrated circuit are exemplified as the optical component, but the optical component is not limited to these. A mode for modulating a phase for each unit structure is not limited to the above embodiments and modifications. For example, the phase can also be modulated for each unit structure by making a shape of the film 21 different between unit structures. However, as in the above embodiments and modifications, it is easier to control the phase for each unit structure by setting a relative position of a center line of a slit with respect to a center line of a unit structure or a width of a slit for each unit structure. In the above embodiments, the APD is exemplified as the photodiode, but the photodiode is not limited to the APD. That is, instead of the APD 10, another type of photodiode having a light-incidence surface and a light-receiving region may be provided in the above embodiments.

The optical element according to the present disclosure is expressed as follows.

(1) An optical element according to an aspect of the present disclosure includes an optical component and a light-focusing structure. The optical component has a light-incidence surface on which light is incident. The light-focusing structure has a nanostructure provided on the light-incidence surface of the optical component. The nanostructure has a plurality of first unit structures arranged along the light-incidence surface. A period of the plurality of first unit structures is equal to or greater than a wavelength of the light. The light-focusing structure focuses diffracted light by individually modulating a phase of ±n-th order (n>0) diffracted light of the light in each of the plurality of first unit structures.

(2) In the optical element described in (1) above, the optical component may be a photodiode that has a light-receiving region and converts light incident on the light-incidence surface into electrons in the light-receiving region. The light-focusing structure may focus the diffracted light into the light-receiving region.

In the optical elements described in (1) and (2) above, the nanostructure of the light-focusing structure is provided on the light-incidence surface of the photodiode or the optical component. A period of the plurality of first unit structures of the nanostructure is equal to or greater than a wavelength of incident light, and the light-focusing structure focuses diffracted light by individually modulating a phase of ±n-th order (n>0) diffracted light of the incident light in each of the plurality of first unit structures. Such a light-focusing structure focuses ±n-th order (n>0) diffracted light such as ±1st order and ±2nd order, instead of focusing 0-th order light like a conventional meta-lens. Then, a propagation direction of the ±n-th order diffracted light is largely inclined with respect to a propagation direction of the incident light. That is, according to the optical elements described in (1) and (2) above, the propagation direction of the focused light can be largely inclined from a normal direction of the light-incidence surface, as compared with a conventional meta-lens. Then, when a photodiode is included, an optical path in the light-receiving region can be lengthened to increase a quantum efficiency of photoelectric conversion. Furthermore, when the photodiode is an avalanche photodiode, by forming a focal point in the light-receiving region, an avalanche probability can also be increased. As a result, a light receiving sensitivity of the photodiode can be increased.

(3) The optical element described in (1) or (2) above may further include a meta-lens. The nanostructure is located between the meta-lens and the light-incidence surface. The meta-lens has a plurality of second unit structures arranged along the light-incidence surface. A period of the plurality of second unit structures is less than the wavelength of the light. The meta-lens focuses 0-th order light of the light toward the nanostructure. By causing light to be incident on the nanostructure via such a meta-lens, an aperture ratio can be increased to increase an amount of light incident on the photodiode or the optical component.

(4) In the optical element described in any one of (1) to (3) above, the light-focusing structure may further include a first reflecting portion. The first reflecting portion is provided on a side opposite to the nanostructure with respect to the light-incidence surface, and is arranged to enclose the nanostructure when viewed from a direction perpendicular to the light-incidence surface. The first reflecting portion has a first light reflecting surface facing the inside of the enclosure. In this case, at least a part of the diffracted light from the nanostructure is collected at a focal point after being reflected by the first light reflecting surface. Thereby, an optical path in the light-receiving region can be further lengthened to further increase a quantum efficiency of photoelectric conversion.

(5) In the optical element described in any one of (1) to (4) above, the light-focusing structure may further include a second reflecting portion. The second reflecting portion is provided on a side opposite to the nanostructure with respect to the light-incidence surface. The second reflecting portion has a second light reflecting surface facing toward the light-incidence surface. In this case, at least a part of the diffracted light from the nanostructure is collected at a focal point after being reflected by the second light reflecting surface. Thereby, an optical path in the light-receiving region can be further lengthened to further increase a quantum efficiency of photoelectric conversion.

(6) In the optical element described in any one of (1) to (5) above, the light-focusing structure may focus the diffracted light by individually modulating a phase of ±2nd or higher order diffracted light in each of the plurality of first unit structures. The larger the order of the diffracted light emitted from the nanostructure, the larger the inclination of the propagation direction of the diffracted light with respect to a normal direction of the light-incidence surface. According to the optical element described in (6) above, the inclination of the propagation direction of the diffracted light can be further increased to further lengthen an optical path in the light-receiving region, and to further increase a quantum efficiency of photoelectric conversion.

(7) In the optical element described in any one of (1) to (6) above, a phase distribution of light emitted from the nanostructure may satisfy a mathematical formula below (where φ_{Lens} (x, y) is the phase at a coordinate position (x, y) on the light-incidence surface, Δ is the wavelength of the light, f is a focal length of the nanostructure, kₓ is an arbitrary coefficient including 0, α is α=π/2−θ (rad), θ is a diffraction angle, and α>0). With such a configuration, for example, the nanostructure can focus the diffracted light.

$${ϕ}_{Lens} ( x , y ) = - \frac{2 π}{λ} ( \sqrt{{x}^{2} + {y}^{2} + {f}^{2}} - f ) + {k}_{x} sin α \qquad [ Math . 2 ]$$

(8) In the optical element described in any one of (1) to (7) above, each of the plurality of first unit structures may have a slit extending in a predetermined direction. Then, a relative position of a center of the slit of each of the plurality of first unit structures with respect to a center of each of the plurality of first unit structures in a direction intersecting the predetermined direction may be determined according to the phase. With such a configuration, for example, the phase of the diffracted light can be individually modulated in each of the plurality of first unit structures.

(9) In the optical element described in any one of (1) to (8) above, the plurality of first unit structures may mainly comprise metal. In this case, by plasmonic diffraction, an inclination of a propagation direction of the diffracted light can be further increased to further lengthen an optical path in the light-receiving region, and to further increase a quantum efficiency of photoelectric conversion.

(10) In the optical element described in any one of (1) to (8) above, the plurality of first unit structures may mainly comprise dielectric material. Even in this case, by causing the nanostructure to emit ±n-th order diffracted light, the effects by the optical elements described in (1) and (2) above can be obtained.

(11) In the optical element described in any one of (1), (3) to (10) above, the photodiode may be an avalanche photodiode. In that case, a focal point can be formed in the light-receiving region to increase an avalanche probability. As a result, a light receiving sensitivity of the photodiode can be further increased.

What is claimed is:

1. An optical element comprising:
an optical component having a light-incidence surface on which light is incident; and
a light-focusing structure comprising a nanostructure provided on the light-incidence surface of the optical component, the nanostructure comprising a plurality of first unit structures arranged along the light-incidence surface, a period of the plurality of first unit structures being equal to or greater than a wavelength of the light, and the light-focusing structure focusing ±n-th order (n>0) diffracted light of the light by individually modulating a phase of the diffracted light in each of the plurality of first unit structures.

2. The optical element according to claim 1,
wherein the optical component is a photodiode that has a light-incidence surface and a light-receiving region and is configured to convert the light incident on the light-incidence surface into electrons in the light-receiving region, and
the light-focusing structure focuses the diffracted light into the light-receiving region.

3. The optical element according to claim 1, further comprising a meta-lens,
wherein the nanostructure is located between the meta-lens and the light-incidence surface,
the meta-lens comprises a plurality of second unit structures arranged along the light-incidence surface,
a period of the plurality of second unit structures is less than the wavelength of the light, and
the meta-lens focuses 0-th order light of the light toward the nanostructure.

4. The optical element according to claim 1,
wherein the light-focusing structure further comprises a first reflecting portion,
the first reflecting portion is provided on a side opposite to the nanostructure with respect to the light-incidence surface, is arranged to enclose the nanostructure when viewed from a direction perpendicular to the light-incidence surface, and has a first light reflecting surface facing an inside of an enclosure.

5. The optical element according to claim 1,
wherein the light-focusing structure further comprises a second reflecting portion,
the second reflecting portion is provided on a side opposite to the nanostructure with respect to the light-incidence surface and has a second light reflecting surface facing toward the light-incidence surface.

6. The optical element according to claim 1,
wherein the light-focusing structure focuses the diffracted light by individually modulating a phase of ±2nd or higher order diffracted light in each of the plurality of first unit structures.

7. The optical element according to claim 1,
wherein a phase distribution of light emitted from the nanostructure satisfies a mathematical formula below:
$${ϕ}_{Lens} ( x , y ) = - \frac{2 π}{λ} ( \sqrt{{x}^{2} + {y}^{2} + {f}^{2}} - f ) + {k}_{x} sin α \qquad [ Math . 1 ]$$
(where φ_{Lens} (x, y) is the phase at a coordinate position (x, y) on the light-incidence surface, λ is the wavelength of the light, f is a focal length of the nanostructure, kₓ is an arbitrary coefficient including 0, α is α=π/2−θ (rad), θ is a diffraction angle, and α≥0).

8. The optical element according to claim 1,
wherein each of the plurality of first unit structures has a slit extending in a predetermined direction, and
a relative position of a center of the slit of each of the plurality of first unit structures with respect to a center of each of the plurality of first unit structures in a direction intersecting the predetermined direction is determined according to the phase.

9. The optical element according to claim 1,
wherein the plurality of first unit structures mainly comprise metal.

10. The optical element according to claim 1,
wherein the plurality of first unit structures mainly comprise dielectric material.

11. The optical element according to claim 2,
wherein the photodiode is an avalanche photodiode.
